(19) United States
(12) Patent Application Publication
(10) Pub. No.: US 2026/0215238 A1
(43) Pub. Date: Jul. 23, 2026

(54) OVERLAY CORRECTION IN SEMICONDUCTOR DEVICE MANUFACTURING

(71) Applicant: TEL Manufacturing and Engineering of America, Inc., Chaska, MN (US)

(72) Inventors: Junichi Kitano, Chaska, MN (US); Angelique Raley, Albany, NY (US); Luis Fernandez, North Chelmsford, MA (US); Robert William Heussner, Hillsboro, OR (US)

(21) Appl. No.: 19/330,585

(22) Filed: Sep. 16, 2025

Related U.S. Application Data
(60) Provisional application No. 63/747,659, filed on Jan. 21, 2025.
(60) Provisional application No. 63/810,499, filed on May 22, 2025.

(51) Int. Cl. H01L 21/768; H01L 21/66

(52) U.S. Cl. CPC H10W 20/081; H10P 74/203; H10W 20/056

(57) ABSTRACT

A method is provided for processing a substrate to correct overlay misalignment between patterned layers. The method includes measuring an overlay misalignment between a feature of a first patterned layer and an opening of a second patterned layer that is disposed over the first patterned layer. Based on the measured overlay misalignment, the method performs a location specific directional etching process to extend a first dimension of the opening in a first direction. The method also performs a location specific deposition process to reduce a second dimension of the opening in a second direction different from the first direction. The location specific directional etching process and location specific deposition process work together to reduce the overlay misalignment.

### CROSS-REFERENCE TO RELATED APPLICATIONS

This application claims the benefit of U.S. Provisional Applications 63/747,659, filed on Jan. 21, 2025 and 63/810,499 filed May 22, 2025, which applications are hereby incorporated herein by reference.

### TECHNICAL FIELD

The present invention relates generally to a method for semiconductor device manufacturing, and, in particular embodiments, to a method for overlay correction in semiconductor device manufacturing.

### BACKGROUND

Semiconductor devices often comprise a multilayer structure including a stack of various material layers formed by processing a substrate through a sequence of patterning levels. The processing at each patterning level may comprise deposition, lithography, and etching to form or modify structures in a layer of the substrate. A lithography technique is used to pattern features, such as lines, trenches, pillars and holes in a masking layer. The patterned mask is then used to process exposed portions of underlying layers through selective etching processes. The substrate is coated with resist and exposed to a pattern of actinic radiation over areas of the substrate. With the resist exposed, the substrate is transferred to a developer, where the resist is developed to print a relief pattern. After printing the relief pattern, the pattern is transferred to underlying layers by selective etching using the patterned resist as an etch mask.

The structures fabricated in each of the various patterned layers have to be aligned vertically for the stacked layers to collectively form the multilayer structure. An optical alignment procedure is executed prior to exposing areas to the radiation pattern. The lithography system analyzes low intensity images of the radiation pattern to detect alignment marks in a layer patterned at an earlier patterning level and, based on the analysis, the optics and the movable stage are adjusted to overlay the radiation pattern with the existing patterned layers of the substrate. After completing the alignment, the resist is exposed and developed.

### SUMMARY

In accordance with one aspect of the present invention, a method is provided for processing a substrate. The method comprises measuring an overlay misalignment between a feature of a first patterned layer and an opening of a second patterned layer that is disposed over the first patterned layer. Based on the measured overlay misalignment, the method performs a location specific directional etching process to extend a first dimension of the opening in a first direction and performs a location specific deposition process to reduce a second dimension of the opening in a second direction different from the first direction. The location specific directional etching process and location specific deposition process collectively reduce the overlay misalignment.

In accordance with another aspect of the present invention, a method is provided for processing a substrate comprising location specific correction across multiple regions. The method comprises providing a substrate comprising a second patterned layer disposed over a first patterned layer, and measuring overlay misalignments across the substrate to generate an overlay misalignment map between the second patterned layer and the first patterned layer. Location specific correction parameters are generated to reduce the overlay misalignments based on the overlay misalignment map. Based on the location specific correction parameters at a first location, a first location specific directional process is performed selectively at the first location to reduce the overlay misalignment at the first location. Based on the correction parameters at a second location different from the first location, the first location specific directional process is performed selectively at the second location to reduce the overlay misalignment at the second location.

In accordance with yet another aspect of the present invention, a method is provided for processing a substrate using selective sidewall modification. The method comprises forming an opening in a second patterned layer over a first patterned layer, where the opening comprises a first sidewall and a second sidewall different from the first sidewall. Material is deposited in the opening along the first sidewall but not along the second sidewall to reduce a first dimension of the opening. The second sidewall is etched at an angle relative to the second patterned layer to increase a second dimension of the opening.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate cross-sectional views of a method for overlay misalignment correction using location specific directional processes, in accordance with an embodiment;

FIGS. 2A-2F illustrate top views corresponding to the cross-sectional views of FIGS. 1A-1F, in accordance with an embodiment;

FIGS. 3A-3D illustrate top views of a variation showing trench structures instead of via openings for overlay correction, in accordance with an embodiment;

FIGS. 4A-4B illustrate cross-sectional views of an alternative embodiment using conformal deposition followed by location specific directional etching, in accordance with an embodiment;

FIGS. 5A-5B illustrate top views corresponding to the cross-sectional views of FIGS. 4A-4B, in accordance with an embodiment;

FIGS. 6A-6F illustrate cross-sectional views of an embodiment demonstrating location specific directional processing with customized correction parameters, in accordance with an embodiment;

FIGS. 7A-7F illustrate top views corresponding to the cross-sectional views of FIGS. 6A-6F, in accordance with an embodiment;

FIGS. 8A-8C illustrate cross-sectional views of method variations for overlay misalignment correction using location specific directional processes, in accordance with an embodiment;

FIGS. 9A-9B illustrate cross-sectional views of an overlay correction method starting with location specific deposition, in accordance with an embodiment;

FIGS. 10A-10C illustrate cross-sectional views of another overlay correction method starting with location specific deposition, in accordance with an embodiment;

FIGS. 11A-11B illustrate cross-sectional views of same-material deposition for overlay correction, in accordance with an embodiment;

FIGS. 12A-12B illustrate cross-sectional views of an alternative same-material deposition for overlay correction, in accordance with an embodiment;

FIG. 13 illustrates a process flow diagram for an overlay correction method, in accordance with an embodiment; and

FIG. 14 illustrates a process flow diagram for a location specific processing method, in accordance with an embodiment.

### DETAILED DESCRIPTION OF ILLUSTRATIVE EMBODIMENTS

Overlay misalignment between patterned layers presents challenges in multilayer device manufacturing, particularly as feature dimensions continue to shrink and alignment tolerances become increasingly stringent. During the fabrication process, photolithographic patterning may result in openings or features in one layer being positionally offset from their intended alignment with underlying features in previous layers. This misalignment can occur due to various factors including equipment variations, thermal effects, substrate distortions, or process-induced shifts. When features in one layer are not properly aligned with underlying features, the resulting misalignment can lead to electrical performance degradation, increased resistance, unwanted capacitance effects, reduced contact area, and ultimately decreased device yield and reliability.

The misaligned features may be widened to compensate for positional errors by increasing the feature dimensions so that even with misalignment, sufficient overlap is maintained between layers. However, this widening approach may create problems by reducing the spacing between adjacent features in the same layer. The reduced spacing can potentially cause electrical shorts, increased crosstalk between neighboring features, and non-uniform electrical characteristics across the device. Additionally, conformal deposition techniques have been used to apply material uniformly across the entire substrate, followed by multiple etching steps to achieve the desired corrections. However, this multi-step approach may require three to four separate processing steps, increasing manufacturing complexity, processing time, and potential for introducing additional errors or variations.

Furthermore, conformal deposition may apply uniform adjustments across the entire substrate, failing to address the location specific nature of overlay errors that can vary across different regions of a wafer. Overlay misalignment is often non-uniform, with different areas of the substrate experiencing different types and magnitudes of positional errors. A blanket correction approach that treats all areas identically may overcorrect some regions while undercorrecting others, leading to suboptimal results and continued performance variations across the device.

Embodiments of the present disclosure address these challenges by providing methods for selective overlay correction using location specific directional processes. The disclosed approach combines location specific directional etching to expand openings in specific directions where needed and location specific deposition to backfill portions of openings in other directions, thereby correcting misalignment while maintaining proper spacing between adjacent features. By employing location specific processing guided by overlay metrology measurements, the disclosed methods may provide customized corrections for different regions of the substrate based on their individual misalignment characteristics. This targeted approach results in improved electrical performance uniformity, better device yield, more precise alignment control, and enhanced feature density compared to conventional blanket correction approaches. The selective nature of the correction process ensures that properly aligned features remain unaffected while misaligned features receive appropriate correction tailored to their specific positional errors. Additionally, the disclosed methods may achieve overlay correction with fewer processing steps, reducing manufacturing complexity while improving spatial resolution through advanced beam control techniques such as gas cluster beam processing with location specific parameter adjustment.

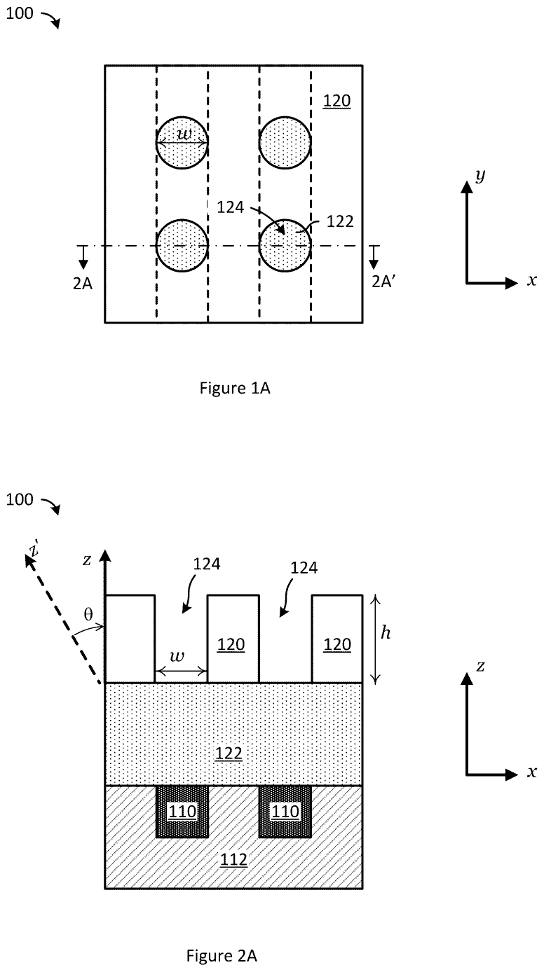

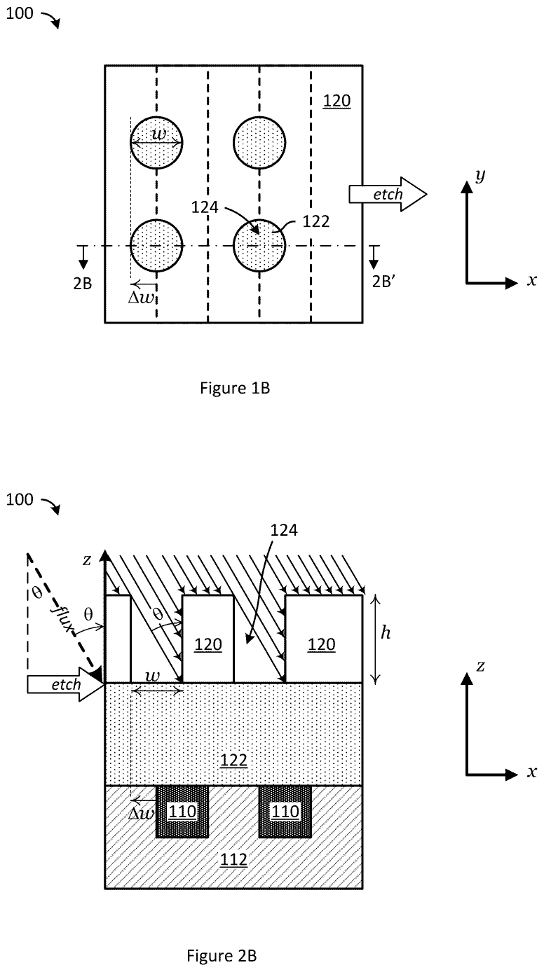

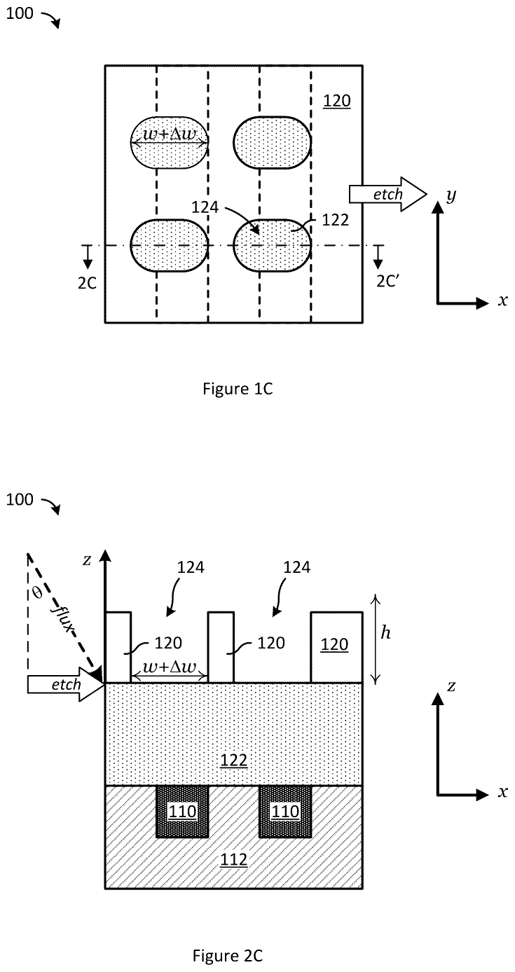

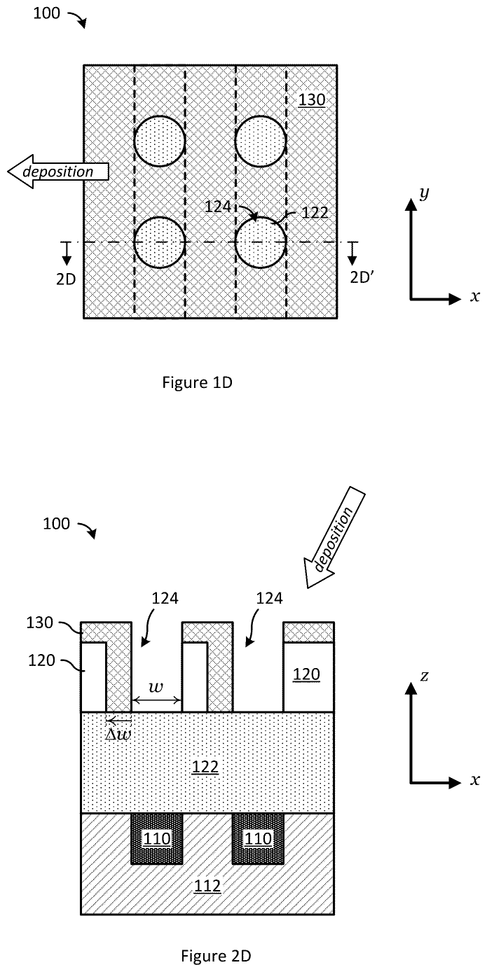

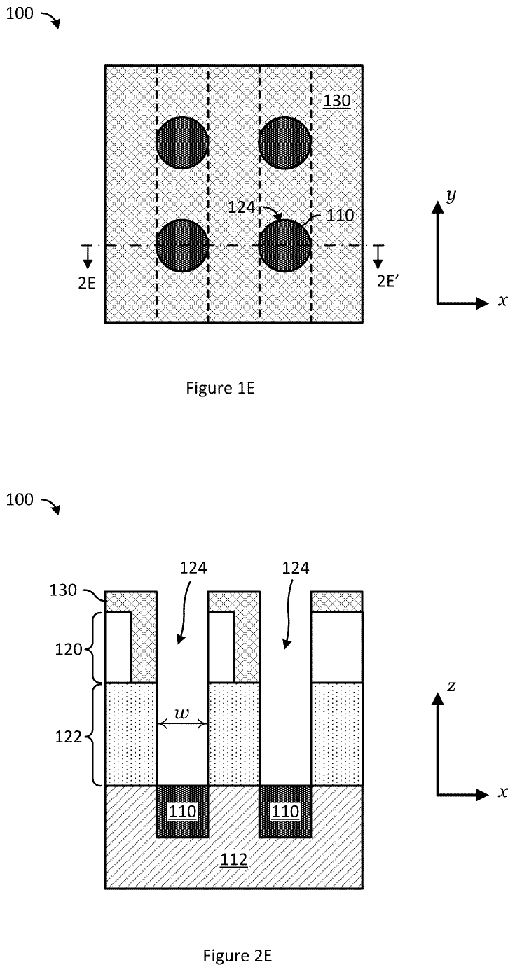

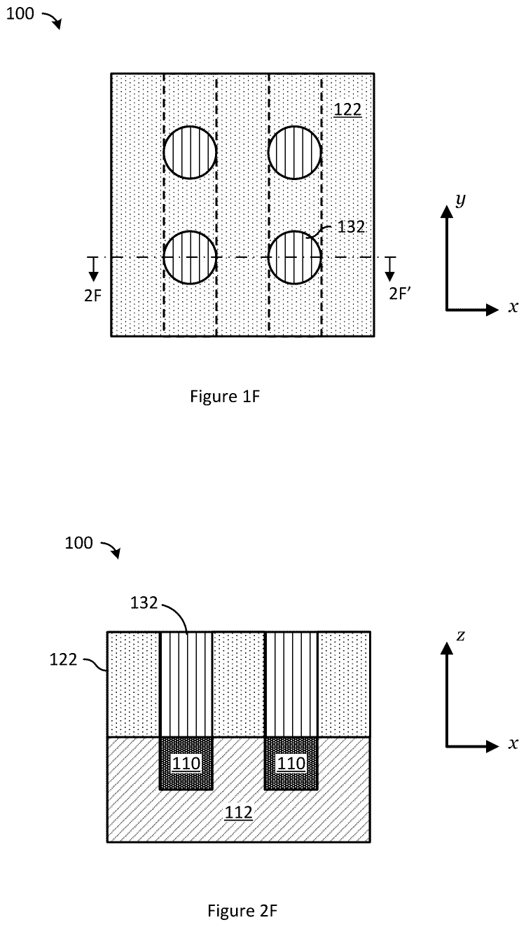

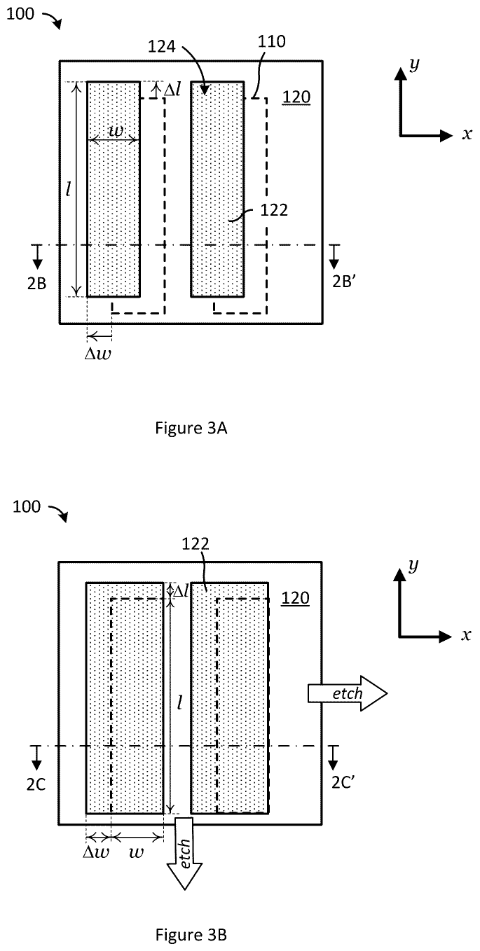

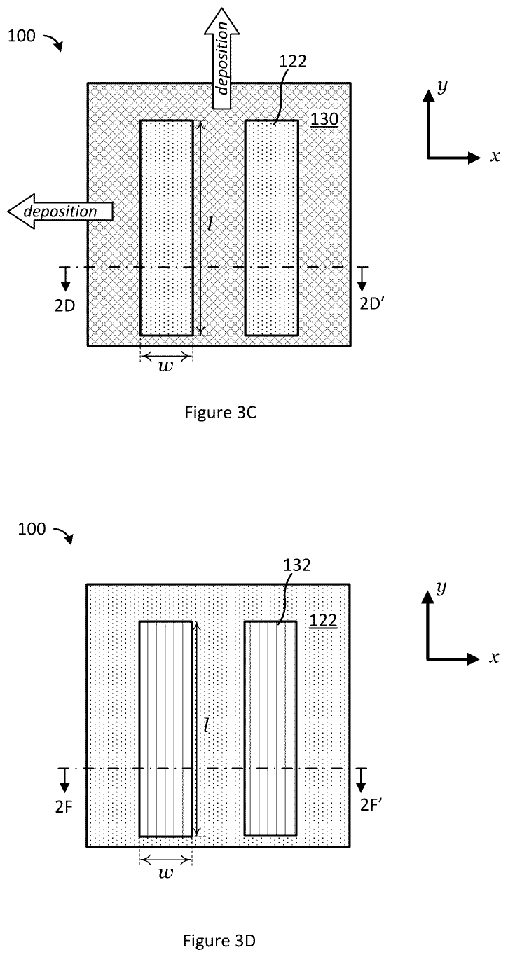

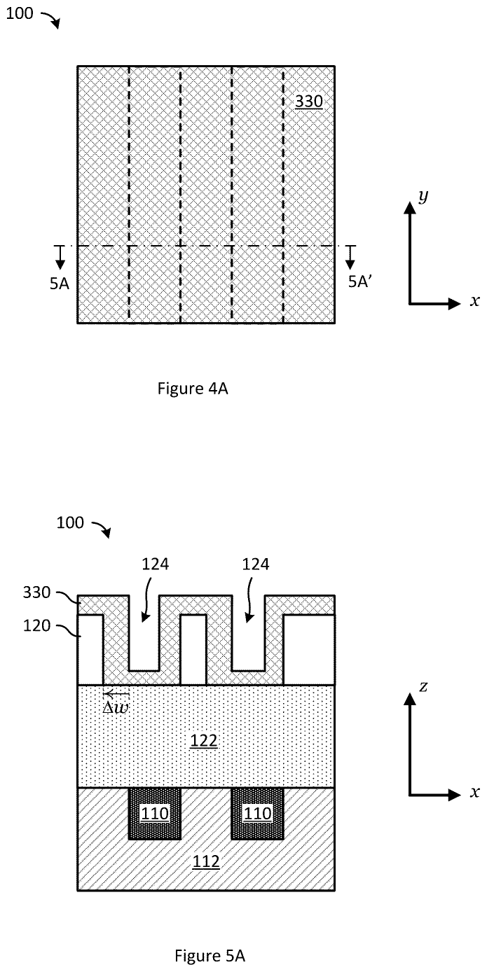

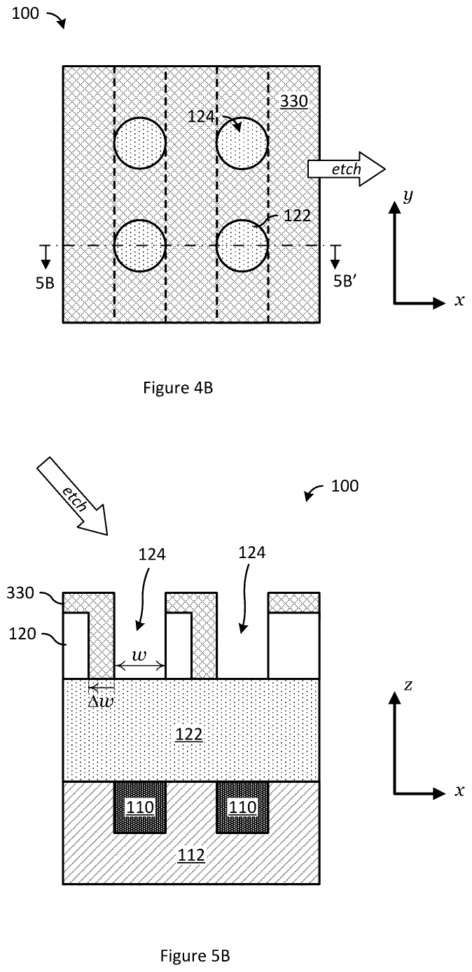

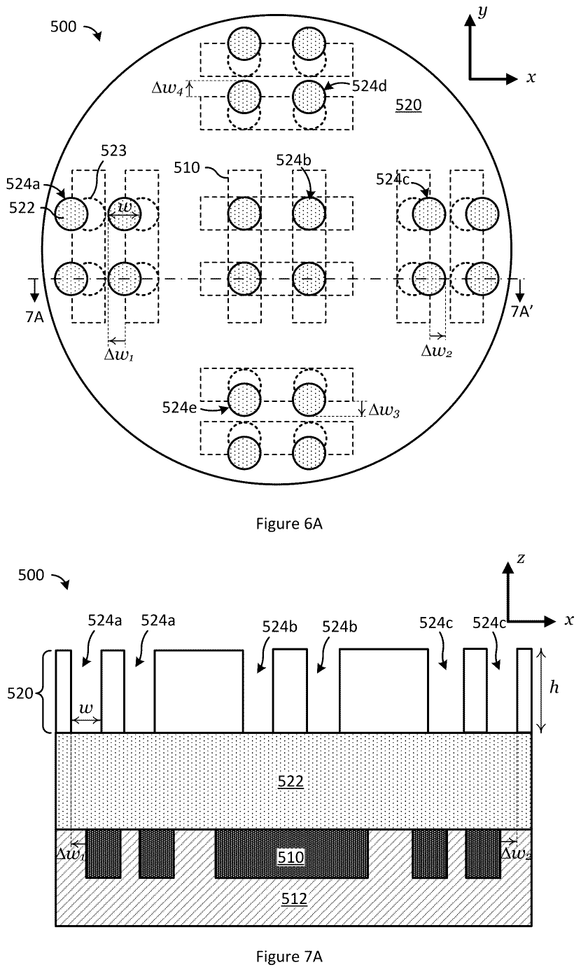

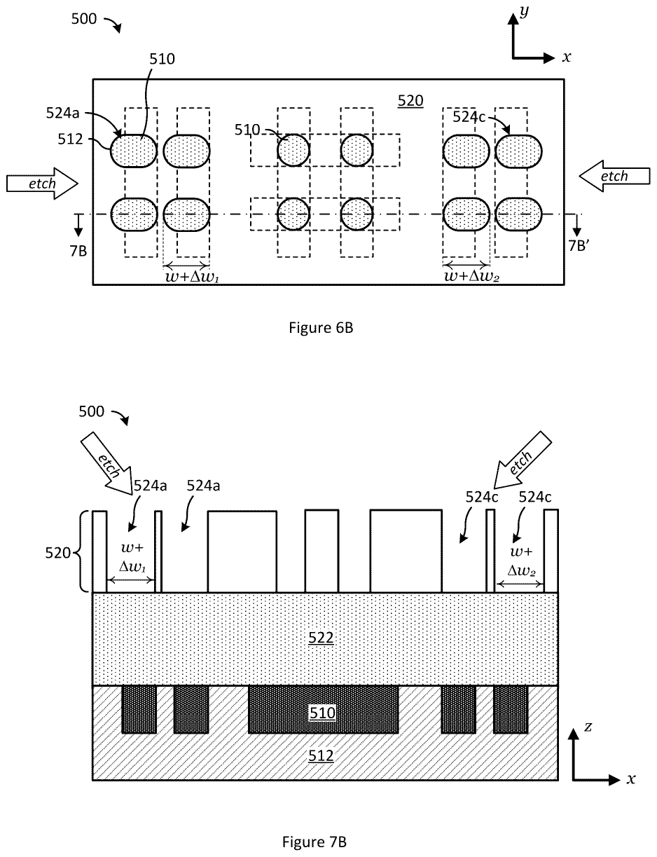

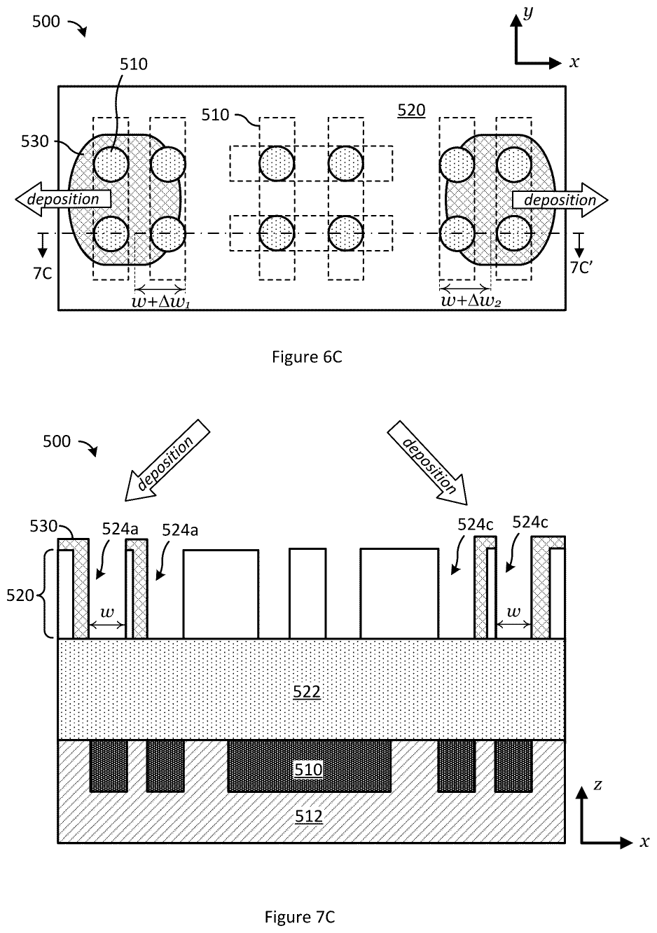

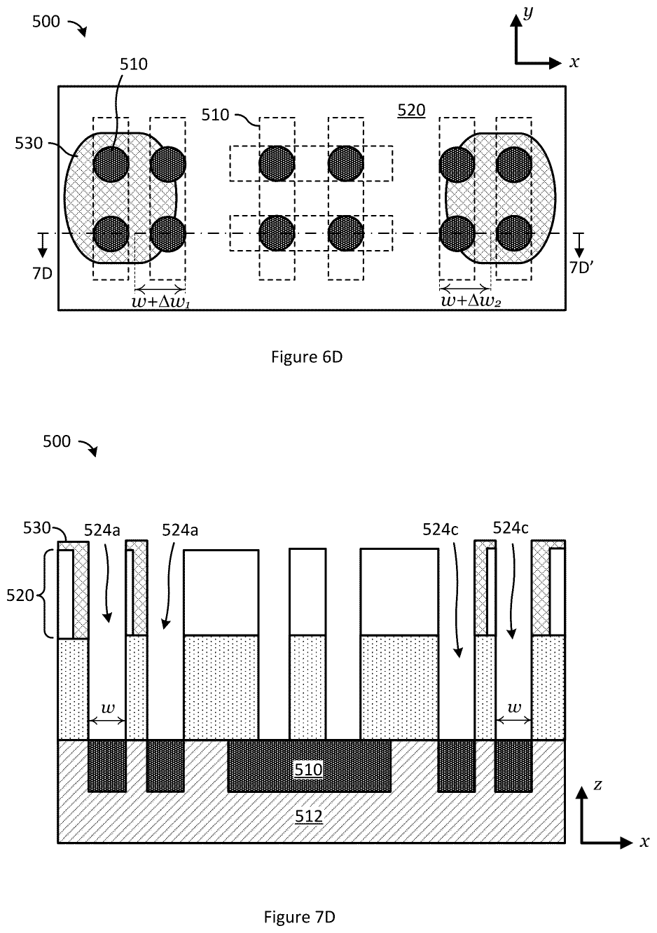

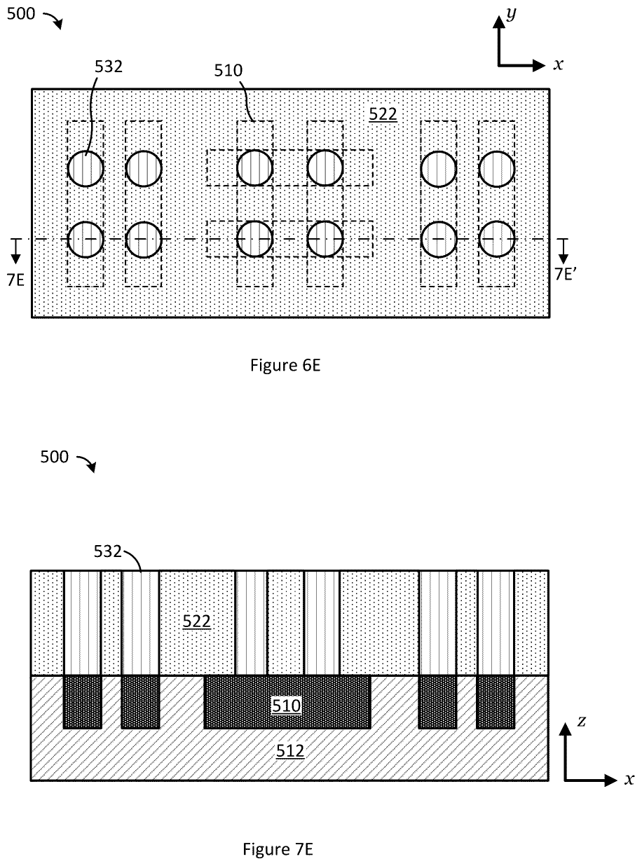

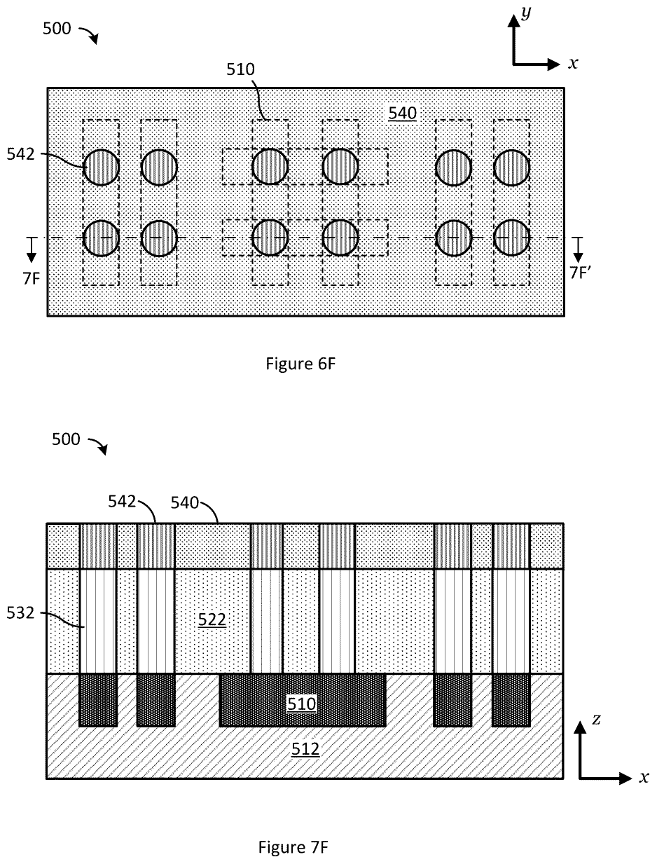

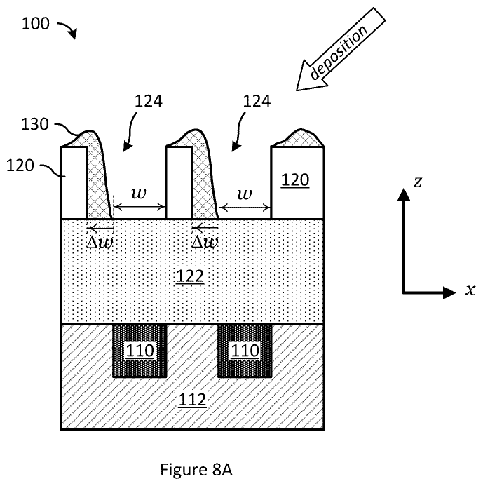

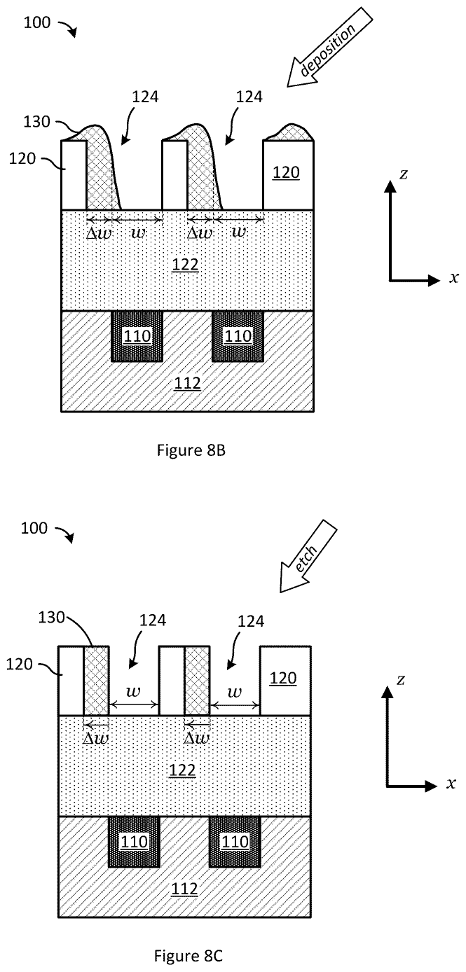

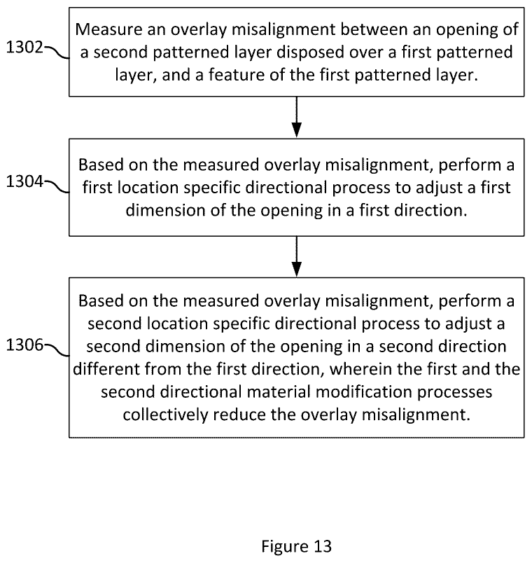

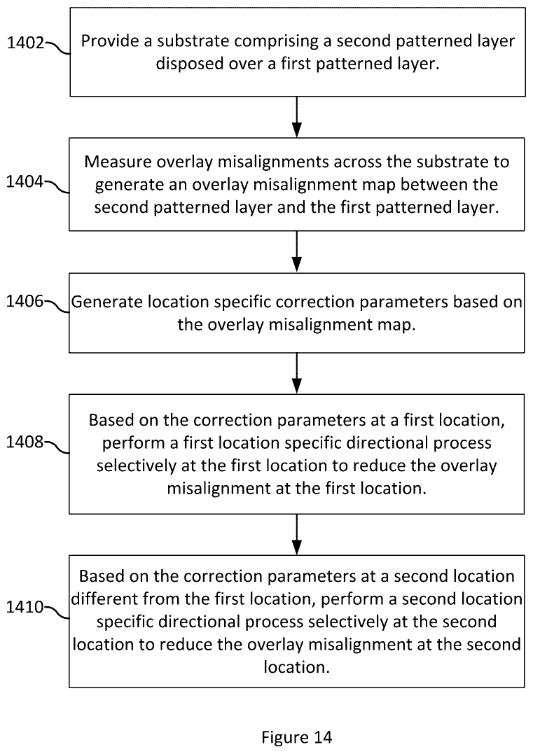

Embodiments of the disclosure are described in the context of the accompanying drawings. An embodiment of overlay misalignment correction using location specific directional etching followed by location specific deposition is described using FIGS. 1A-1F and 2A-2F. A variation showing trench structures instead of via openings is illustrated in FIGS. 3A-3D. An alternative embodiment using conformal deposition followed by location specific directional etching is shown in FIGS. 4A-4B and 5A-5B. An additional embodiment demonstrating location specific directional processing with customized correction parameters is described using FIGS. 6A-6F and 7A-7F. Alternative embodiments utilizing location specific deposition variations and deposition-first approaches are illustrated in FIGS. 8A-12B. Process flow diagrams for the general overlay correction method and location specific processing method are presented in FIGS. 13 and 14, respectively.

FIGS. 1A-1F and 2A-2F illustrate cross-sectional views and corresponding top views of a method for overlay misalignment correction using location specific directional processes, in accordance with an embodiment. In this embodiment, the location specific directional processes are location specific to correct for overlay error in aligning a pattern of holes to a pattern of lines formed in a layer of the substrate. The correction may be achieved through a location specific directional etching process to etch sidewalls of the openings or a location specific directional deposition process to backfill sidewalls of the openings. The location specific directional deposition may also be referred below as location specific deposition. The example embodiment may be of advantage when the pattern of openings is, for example, an etch mask for etching via openings in an upper interlayer dielectric (ILD2) layer for fabricating vias connecting to the pattern of lines, where the pattern of lines is a pattern of parallel metal lines already formed in the substrate inlaid in a lower interlayer dielectric (ILD1) layer.

FIG. 1A illustrates a top view of a substrate 100 having a second patterned layer 120 comprising a pattern of openings (e.g., holes) aligned to a first patterned layer 110 comprising a pattern of features (e.g., parallel lines). FIG. 2A illustrates a respective cross-sectional view of the substrate 100 along line 2A-2A′. The views shown in FIG. 1A and FIG. 2A are at a first location of the major surface of the second patterned layer 120, where there is no overlay error. In this example, features of the first patterned layer 110 are parallel lines formed inlaid in a first separation layer 112, as illustrated in FIG. 2A. In some embodiments, the first patterned layer 110 in FIG. 2A may comprise parallel metal lines, and the first separation layer 112 may be a lower interlayer dielectric layer. In an embodiment, the first patterned layer 110 may comprise copper and the first separation layer 112 may comprise a low dielectric constant (low-k) silicon oxide. Lateral positions of the lines of the first patterned layer 110 are indicated by dashed rectangles in FIG. 1A.

In some embodiments, a second separation layer 122 may be formed covering the first patterned layer 110 and the first separation layer 112, and the second patterned layer 120 may be formed over the second separation layer 122, as illustrated in FIG. 2A. In various embodiments, the second patterned layer 120 may be a hard mask layer comprising a pattern of holes, such as the openings 124, shaped like a circle having a width w, as shown in FIG. 1A. The openings 124 may expose a surface of the second separation layer 122. The second separation layer 122 may be an upper interlayer dielectric layer. In some embodiments, the second patterned layer 120 may comprise silicon nitride and the second separation layer 122 may comprise a low dielectric constant (low-k) silicon oxide.

In various embodiments, the second separation layer 122 may be a stack of multiple material layers rather than a single layer. The second separation layer 122 may comprise organic materials, inorganic materials, dielectric materials, or hard mask materials, depending on the specific process integration requirements. For example, the second separation layer 122 may include combinations of organic planarization layers, silicon oxide layers, silicon nitride layers, or other suitable materials arranged in a multilayer stack configuration. In various embodiments, the second patterned layer 120 may comprise various patterning materials including photoresist, metal oxide resist (MOR), chemically amplified resist (CAR), organic planarization layer materials, or hard mask materials such as silicon nitride, silicon oxide, or metal-containing hard masks. The selection of materials for both the second patterned layer 120 and the second separation layer 122 may be optimized based on the specific overlay correction requirements, etch selectivity needs, and integration with the overall device fabrication process.

In the top view of the major surface of the second patterned layer 120 in FIG. 1A, locations in the major surface may be described by rectangular coordinates (x, y) along an x-axis and a y-axis orthogonal to the x-axis, where (0, 0) is the location of a center of the major surface of the second patterned layer 120. As shown in FIG. 1A, the parallel lines of the first patterned layer 110 are parallel to the y-direction. As indicated in FIG. 2A, the z-axis is normal to the major surface. If there were a flux, for example, at some other locations, as described further below, the flux direction would be opposite a reference direction, the reference direction being that of a z′-axis shown as a dashed arrow in FIG. 2A. The angle, θ,between the z-axis and the z′-axis, referred to as tilt angle, indicates that the substrate 100 has been tilted clockwise relative to the reference z′-direction by the tilt angle, θ.

The top view in FIG. 1B and the respective cross-sectional view in FIG. 2B are at a second location of the major surface of the second patterned layer 120 where there is an overlay error in the negative x-direction. The cut plane for the cross-section is marked by a dotted line 2B-2B′ in FIG. 1B. At this location, the center of each through opening 124 may be offset by a distance Δw in the negative x-direction, instead of being directly above the center of the respective line in the first patterned layer 110, as shown in the top-view in FIG. 1B and the cross-sectional view in FIG. 2B. The overlay misalignment or error undesirably reduces a vertical overlap area between each through opening 124 and the respective line in the first patterned layer 110.

In the example embodiment, a first location specific directional process may be performed at the location illustrated in FIG. 1B and FIG. 2B. In various embodiments, the location specific directional process described herein may refer to a material modification process that combine both spatial selectivity and directional control to achieve precise overlay correction. The process parameters in the location specific directional process may be customized and applied selectively to different regions or locations across the substrate based on the local overlay misalignment characteristics at each location, rather than applying uniform processing across the entire substrate. This spatial selectivity may be guided by overlay metrology measurements that generate location specific correction parameters as described below, allowing different areas of the substrate to receive different treatment intensities, directions, or process durations as needed. The orientation and angle of the material modification flux may be controlled during the location specific directional process, whether for etching or deposition, which may enable selective modification of specific sidewalls or regions within individual openings. This directional control may be achieved through techniques such as substrate tilting, beam steering, flux collimation, or controlled particle trajectories that target specific areas within the openings rather than providing isotropic or omnidirectional processing. The combination of location specific and directional control enables the disclosed overlay correction methods to address complex, non-uniform overlay error patterns across a substrate while maintaining precise control over feature dimensions and alignment at each corrected location. This distinguishes from conventional blanket processing methods that apply uniform correction across entire substrates or from purely directional processes that lack location specific customization based on metrology feedback.

The term “directional process” as used herein may refer to material modification processes performed at controlled angles relative to the substrate surface normal, for example, incident beam angles greater than 0 degrees and less than 90 degrees from the substrate surface normal. Directional processes may enable targeting of specific surfaces, sidewalls, or regions within features by controlling the trajectory and orientation of the incident flux, beam, or reactive species. This directional control may be achieved through substrate tilting, beam steering, nozzle positioning, or other orientation control techniques that direct the material modification flux toward desired locations while avoiding or minimizing impact on other surfaces. Directional processes contrast with isotropic or omnidirectional processes that affect all exposed surfaces uniformly regardless of orientation.

The term “angled” as used herein may refer specifically to non-orthogonal processing orientations where the incident flux, beam, or reactive species approaches the substrate surface (e.g., a major surface) at non-perpendicular angles. Angled processing may involve incident angles greater than 0 degrees and less than 90 degrees relative to the substrate surface normal, enabling preferential interaction with sidewalls, sloped surfaces, or specific facets of three-dimensional features. Angled processing may be particularly effective for accessing recessed features, modifying sidewall profiles, or achieving asymmetric material modification patterns that would not be possible with perpendicular processing.

Both directional and angled processing techniques enable spatial selectivity by exploiting geometric effects such as shadowing, line-of-sight limitations, and surface accessibility to achieve location specific material modification. These techniques may be combined with location specific positioning, scanning, or parameter modulation to achieve comprehensive overlay correction across different regions of the substrate while maintaining precise control over feature dimensions and alignment.

The first location specific directional process may adjust a first dimension of the opening 124 in a first direction. In one or more embodiments, the first location specific directional process may be a location specific directional etching process to extend each of the openings 124 (by the first dimension) toward the positive x-direction to compensate for the reduced overlap caused by the overlay error. In various embodiments, the location specific directional etching process may comprise reactive ion etching, ion beam etching, gas cluster beam etching, plasma etching with directional focus, or directional chemical etching using precursors comprising fluorine-containing compounds, chlorine-containing compounds, oxygen-containing compounds, carbon-containing compounds, or hydrogen-containing compounds. Accordingly, the substrate 100 may be tilted appropriately (as described below) and the second patterned layer 120 may be exposed to a particle flux comprising etchants that etch the second patterned layer 120 selective to an exposed portion of the second separation layer 122 at the bottom of each openings 124.

The flux may comprise a mixture of reactive species that interact chemically and inert species that interact physically with the exposed material. In some embodiments, the location specific directional etch process may comprise chemical etching, where etchants remove surface atoms by chemical interactions that form volatile products. In some embodiments, the etching may be physical etching, such as ion milling and sputter etching with a collimated particle flux, where surface atoms are mechanically dislodged by energetic particles, for example, ions accelerated by an electric field. In some embodiments, high energy inert species may be used to enhance a chemical reaction rate between the reactive species and the surface by breaking chemical bonds between the surface atoms. The chemistry may be selected such that the second patterned layer 120 (e.g., silicon nitride) is etched at a higher rate relative to the second separation layer 122 (e.g., low-k silicon oxide). The reactive species may be a reactant gas comprising atoms such as oxygen, fluorine, or chlorine, and the inert species may be an inert gas such as argon, neon, or helium. In various embodiments, the particles may be charge neutral particles (e.g., molecules and neutral radicals) or a mixture of neutral particles and charged particles (e.g., ions). In some embodiments, the gas may comprise non-interacting particles (i.e., single molecules, radicals, and ions), similar to an ideal gas. In some other embodiments, the gas may be a cluster gas comprising particles, which are clusters of atoms or molecules (e.g., about 1,000 to about 10,000 molecules) loosely bound by van der Waals forces. Clusters may be formed by a condensation induced by adiabatic expansion when, for example, compressed gas is released to a vacuum using a supersonic nozzle, resulting in a cluster gas having properties between that of a liquid and a gas. In some embodiments, the cluster gas may be ionized to acquire an average positive charge of about +1e to +10e per cluster, where e is magnitude of electron charge.

In FIG. 2B, the substrate 100 may be rotated clockwise relative to the reference z′-direction by the tilt angle, θ, same as in FIG. 2A. The normal to the major surface (i.e., the z-axis) is tilted relative to the flux direction, indicated in FIG. 2B by a dashed arrow pointing in a direction that is opposite the reference z′-direction. The incident flux is indicated schematically by solid arrows. Tilting the substrate 100 may result in the flux being incident at angle of incidence equal to the tilt angle, θ.

In alternative embodiments, the incident flux (or beam) itself may be tilted or steered to achieve the desired angle of incidence relative to the substrate surface. The beam tilting may be accomplished through various techniques including electrostatic or magnetic beam steering for ion beams, mechanical adjustment of nozzle orientation for gas cluster beams, or optical beam steering for plasma-based processes. In some embodiments, the beam angle may be dynamically adjusted during processing to optimize the etch profile or to sequentially address different sidewalls of the opening 124 without requiring substrate rotation. In some embodiments, multiple beams with different angles may be employed simultaneously to improve throughput. In some embodiments, a single beam may be rapidly repositioned to address different correction requirements across the substrate. In various embodiments, the substrate tilting and beam tilting may be combined to control the angle of incidence of the incident flux to selectively modify specific sidewalls of the openings for overlay correction.

In various embodiments, the incident flux may remove material from the top surface of the second patterned layer 120, which reduces its height, h. In addition, a portion of the sidewall of the openings 124, which is exposed to the flux, gets etched. As the etch advances, it may cause the sidewall to shift laterally along a direction of the etch front, that is, along an orthogonal projection of the flux direction onto the major surface of the second patterned layer 120. The direction of the shift, referred to here as the etch direction is indicated by a block arrow in FIG. 1B and in FIG. 2B. The substrate 100 may be oriented azimuthally such that that the etch direction is parallel to the positive x-direction. The azimuthal angle, also known as twist angle may be adjusted by rotating the wafer azimuthally about a central axis normal to the major surface of the substrate. It is noted that for θ=0° the flux is incident perpendicularly on the major surface, and increasing the tilt angle makes the flux direction less vertical, till at θ=90° the flux is parallel to the major surface. Since the particle flux has to etch the sidewall all the way to the bottom of the through opening 124, the tilt angle has to be less than a maximum value, depending on the height, h, and the width, w, of the through opening 124. In some embodiments, the tilt angle θ may be greater than 0 and smaller than 90°.

The overlay misalignment shown in FIGS. 1B and 2B may be detected and quantified using overlay metrology techniques prior to performing the corrective location specific directional processes. The measuring may be based on overlay metrology comprising optical overlay measurement, or electron beam overlay measurement. In some embodiments, the optical overlay measurement techniques may be imaging-based optical method by utilizing visible or infrared light to analyze alignment marks or gratings formed in different layers, detecting positional offsets through image analysis or interferometric methods. In alternative embodiments, the optical overlay measurement may comprise scatterometry-based overlay measurement by employing the analysis of diffracted light from periodic structures to determine overlay errors with high precision and sensitivity. In some embodiments, electron beam overlay measurement may use scanning electron microscopy or dedicated electron beam metrology tools to directly measure the relative positions of features in different layers with nanometer-scale accuracy. These metrology techniques may provide quantitative measurements of the overlay misalignment magnitude and direction, such as the offset distance Δw in the negative x-direction shown in FIG. 1B, which information is then used to determine the appropriate parameters for the subsequent location specific directional processes. The overlay measurements may be performed at multiple locations across the substrate to generate an overlay misalignment map that guides location specific correction strategies, as will be described in later embodiments.

FIG. 1C illustrates a top view and FIG. 2C illustrates a respective cross-sectional view of the substrate 100 at the location shown in FIG. 1B and FIG. 2B. The views in FIG. 1C and FIG. 2C show the state of the substrate 100 after the location specific etch process is complete. As explained above, the etch process has shifted the sidewall and the associated edge of the openings 124 by a distance Δw in the positive x-direction. This edge displacement increases the width, w, of the openings 124 at this location along the x-direction (i.e., direction of the displacement), which recovers the loss in overlap area caused by the overlay error of Δw in the negative x-direction. Note that the removal of material from the top surface of the second patterned layer 120 may reduce its height to below the original height, h.

FIG. 1D illustrates a top view and FIG. 2D illustrates a respective cross-sectional view of the substrate 100 at the same location after performing a second location specific directional process. The second location specific directional process may adjust a second dimension of the opening 124 in a second direction, wherein the first and the second location specific directional processes may collectively reduce the overlay misalignment. In one or more embodiments, the second location specific directional process may involve a location specific deposition (or location specific directional deposition) of a material 130 to backfill a portion of the extended openings 124. In certain embodiments, the location specific directional deposition may deposit the material 130 over both sidewalls and top surfaces of the second patterned layer 120. In some embodiments, the location specific directional deposition may only deposit the material 130 over sidewalls of the second patterned layer 120. The location specific directional deposition may reduce the opening width from w+Δw back to approximately the original width w, while maintaining the corrected alignment with the underlying features of the first patterned layer 110.

In certain embodiments, the location specific directional deposition process may be achieved through gas cluster beam (GCB) deposition. In some embodiments, the location specific directional deposition process may also be achieved through area selective atomic layer deposition (AS-ALD), location specific atomic layer deposition (LS-ALD), inclined physical vapor deposition (PVD), or other deposition methods with directional focus such as remote plasma deposition, ion beam deposition, or ribbon beam deposition.

In one or more embodiments, the GCB deposition may utilize clusters of atoms or molecules (e.g., about 1,000 to about 10,000 molecules per cluster) that are accelerated toward the substrate at controlled angles and energies, enabling directional material deposition with precise control over deposition location and thickness. In various embodiments, GCB processing may be performed at room temperature, providing advantages in thermal budget management and material compatibility compared to higher temperature processes. The GCB technique may achieve location selective sidewall deposition where material deposits preferentially on specific sidewalls while exhibiting minimal deposition on horizontal surfaces due to shadowing effects from the directional beam geometry. GCB beam sizes may range from approximately 4-5 millimeters to centimeter scale diameters, allowing for location specific processing across different regions of the substrate. The angled orientation of the GCB beam may be precisely controlled to achieve optimal deposition angles for each specific location across the substrate 100. Angled GCB deposition may utilize beam angles ranging from greater than 0 degrees to less than 90 degrees relative to the substrate surface normal, enabling selective targeting of specific sidewalls within the openings 124 while avoiding unwanted deposition on opposing surfaces through line-of-sight control and shadowing effects. In some embodiments, GCB deposition may be enhanced using co-gas chemistry, such as argon, C₄F₈ or other carbon-containing compounds, which may provide additional carbon sources and improve deposition characteristics. The co-gas may interact at or near the substrate surface to enhance location specific directional deposition. Unlike ion beam techniques that utilize individual ions at high energies, GCB employs clusters of molecules at relatively lower per-atom energies, enabling deposition rather than etching while maintaining directional control.

The AS-ALD may be used to selectively deposit material. Such a process employs material selectivity where the material deposits preferentially on one specific exposed material relative to another material based on surface chemistry differences, allowing for bottom-up selective growth on targeted materials while inhibiting growth on others. In LS-ALD, an ALD cycle may be contained within a movable nozzle that can be positioned at specific substrate locations to provide spatially controlled deposition. Inclined PVD may involve depositing material at non-zero angles relative to the substrate normal, enabling directional material delivery to specific sidewalls or regions of the openings. Remote plasma deposition with directional focus may use plasma-generated reactive species that are directed toward specific areas of the substrate through controlled beam focusing or collimation techniques. Ion beam deposition and ribbon beam deposition may provide highly directional material delivery through accelerated ion beams that can be precisely controlled in terms of angle, energy, and spatial distribution to achieve accurate and precise material placement within the openings.

In various embodiments, the location specific deposition process may be performed using angled deposition techniques where the deposition flux approaches the substrate at non-perpendicular angles. Angled location specific deposition may enable preferential material placement on specific sidewalls or surfaces within the openings (e.g., openings 124) while minimizing deposition on other surfaces through geometric shadowing effects.

In various embodiments, the deposited material 130 may comprise materials selected based on the composition and properties of the second patterned layer 120 and the specific process integration requirements. For example, if the second patterned layer 120 comprises photoresist (PR), the deposited material 130 may comprise organic materials, carbon-containing compounds, or other photoresist-compatible materials that provide suitable selectivity and process compatibility. If the second patterned layer 120 comprises MOR, the deposited material 130 may comprise metal oxide materials, inorganic compounds, or other materials that exhibit appropriate location specific deposition characteristics on MOR surfaces. When the second patterned layer 120 comprises hard mask materials such as silicon nitride or silicon oxide, the deposited material 130 may comprise complementary hard mask materials, silicon-containing compounds, or other inorganic materials that provide the desired selectivity and etch resistance properties. In various embodiments, the deposited material 130 may comprise carbon-containing materials for carbon-based mask layers, silicon-containing materials for silicon-based layers, or metal-containing materials for metal-based mask systems. The selection of deposited material 130 is optimized to achieve location specific deposition on the desired surfaces while maintaining compatibility with subsequent processing steps and providing the necessary mechanical and chemical properties for effective overlay correction.

FIG. 8A illustrates a cross-sectional view of a location specific deposition variation for overlay correction, in accordance with an embodiment. This embodiment illustrates an alternative approach to the location specific deposition process described in FIGS. 1D and 2D, where the deposited material 130 (covering both sidewalls and top surfaces of the second patterned layer 120) may exhibit a non-uniform or irregular profile rather than a rectangular cross-section. In various embodiments, the location specific deposition process may result in material profiles that vary depending on the specific deposition technique employed, process parameters, and substrate geometry. For example, when using gas cluster beam deposition with directional control, the deposited material 130 may form profiles that follow the natural deposition characteristics of the beam, potentially creating curved, tapered, or asymmetric shapes rather than rectangular geometries. This variation may occur due to factors such as beam angle distribution, shadowing effects from adjacent structures, surface energy differences, or material flow characteristics during deposition. While the deposited material profile may not be uniform, the location specific deposition may still reduce the opening width from w+Δw back to approximately the original width w, while maintaining the corrected alignment with the underlying features of the first patterned layer 110.

FIGS. 8B-8C illustrate cross-sectional views of a location specific deposition followed by an etching process, in accordance with an embodiment. This embodiment demonstrates another variation to the location specific deposition process described in FIGS. 1D and 2D, utilizing a corrective etching to achieve precise dimensional control.

FIG. 8B shows the result after performing location specific deposition where the deposited material 130 may be deposited to reduce dimension of the opening 124 by more than the target correction amount Δw. In this embodiment, the location specific deposition process may overcompensate for the overlay misalignment, resulting in an opening width that is smaller than the desired final dimension w. This overdeposition approach may provide process margin and enable subsequent fine-tuning through controlled material removal. The deposited material 130 may also be deposited on the top surface of the second patterned layer 120, creating a continuous film that extends beyond the opening sidewalls.

FIG. 8C illustrates the result after applying an etching process to remove excess deposited material 130 and achieve the target opening dimension w. The etching process may comprise location specific directional etching that selectively removes material from specific regions within the opening 124 while preserving material in other areas to maintain the overlay correction. In various embodiments, the location specific directional etching may be achieved through techniques such as angled ion beam etching, gas cluster beam etching, or plasma etching with controlled directionality, similar to the location specific directional etching processes described in previous embodiments. The etching process may also remove the deposited material 130 from the top surface of the second patterned layer 120, creating a clean interface for subsequent processing steps.

In alternative embodiments, the etching process in FIG. 8C may be achieved through non-directional etching techniques such as isotropic plasma etching, chemical etching, or other uniform material removal processes. While non-directional etching may remove material uniformly from all exposed surfaces, the process parameters may be controlled to achieve the desired dimensional correction while maintaining the overlay alignment benefits. The choice between directional and non-directional etching may depend on factors such as material selectivity requirements, process integration constraints, and the specific geometry of the features being corrected.

FIG. 1E illustrates a top view and FIG. 2E illustrates a respective cross-sectional view of the substrate 100 at the same location shown in FIGS. 1B-1D. In this step, the second patterned layer 120 after location specific directional processes may be used as an etch mask to transfer the pattern of the corrected openings 124 into the underlying second separation layer 122. The etching process may remove portions of the second separation layer 122 that are exposed through the openings 124, creating openings that extend deeper into the substrate structure.

The etching process may be a selective etch that removes the material of the second separation layer 122 at a higher rate compared to the materials of the second patterned layer 120, the deposited material 130 and the first patterned layer 110. In various embodiments where the second separation layer 122 comprises a low dielectric constant silicon oxide and the second patterned layer 120 comprises silicon nitride, the etch chemistry may be selected to provide selectivity between these materials. The etch process may be anisotropic to maintain the corrected lateral dimensions of the openings 124 while extending them vertically through the second separation layer 122.

As shown in FIG. 2E, the etching process may create openings in the second separation layer 122 that align with the corrected openings 124 in the second patterned layer 120. The cross-sectional view in FIG. 2E shows that the openings 124 now extend through both the second patterned layer 120 and the second separation layer 122, approaching the underlying first patterned layer 110.

FIG. 1F illustrates a top view and FIG. 2F illustrates a respective cross-sectional view of the substrate 100 at the same location after performing a conductive material deposition process to fill the corrected openings and establish electrical connections to the underlying features of the first patterned layer 110. In this step, conductive material 132 may be deposited to fill the openings 124 that extend through the second separation layer 122, creating electrical pathways between upper device levels and the features of the first patterned layer 110. In various embodiments, the first seconded patterned layer 120 and the deposited material 130 may be removed before the conductive material deposition process.

The conductive material deposition process may comprise various techniques such as physical vapor deposition (PVD), chemical vapor deposition (CVD), atomic layer deposition (ALD), or electrochemical plating methods. In various embodiments, the conductive material 132 may comprise metals such as copper, tungsten, aluminum, or other suitable conductive materials depending on the specific application requirements. In some embodiments, the deposition process may include barrier layer formation prior to the main conductive fill to prevent diffusion of the conductive material into surrounding dielectric layers. In some embodiments, a seed layer may be deposited before the main conductive material to promote uniform nucleation and growth.

As shown in FIG. 2F, the conductive material 132 may fill the corrected openings 124, forming electrical connections or vias that extend from the upper surface down to the features of the first patterned layer 110. The cross-sectional view demonstrates that the overlay correction achieved through the previous location specific directional processes results in well-centered conductive connections with improved alignment to the underlying metal lines. The corrected openings maintain the original width w, ensuring proper spacing between adjacent conductive features while providing reliable electrical contact.

In some embodiments, the conductive material 132 may cover top surfaces of the second separation layer 122. In some embodiments, a planarization process may be performed to remove excess conductive material 132 from the upper surface and create a smooth, planar topography suitable for subsequent processing steps.

The planarization process may comprise chemical mechanical planarization (CMP), which combines chemical etching and mechanical polishing to selectively remove material from top surface of the substrate 100. Alternative planarization methods may include etch-back processes, reactive ion etching with controlled selectivity, or other suitable material removal techniques. The planarization process may remove the excess conductive material 132 and deposited material 130 that extend above the desired level, while preserving these materials within the corrected openings 124 to maintain the electrical connections to the features of the first patterned layer 110.

While the above embodiments describe the use of metal materials for the conductive material 132 and the features of the first patterned layer 110, various alternative materials and applications may benefit from the disclosed overlay correction techniques. In some embodiments, the features may comprise semiconductor materials such as doped silicon, germanium, or compound semiconductors for applications in photonic devices, where precise alignment between optical waveguides in different layers is critical for efficient light coupling. In other embodiments, the materials may comprise transparent conductive oxides such as indium tin oxide (ITO) or zinc oxide for display applications, where accurate alignment between pixel electrodes and underlying circuitry affects display uniformity and performance. For micro-electromechanical systems (MEMS) applications, the features may comprise structural materials such as polysilicon, silicon carbide, or metal alloys, where precise alignment between mechanical elements in different layers determines device functionality and reliability. In biomedical device applications, the features may comprise biocompatible materials such as titanium, platinum, or conductive polymers, where accurate alignment between sensor elements and interconnects affects device sensitivity and performance. Additionally, for three-dimensional memory applications, the features may comprise phase-change materials, resistive switching materials, or floating gate structures, where precise alignment between memory cells and access lines is required for proper device operation and data integrity.

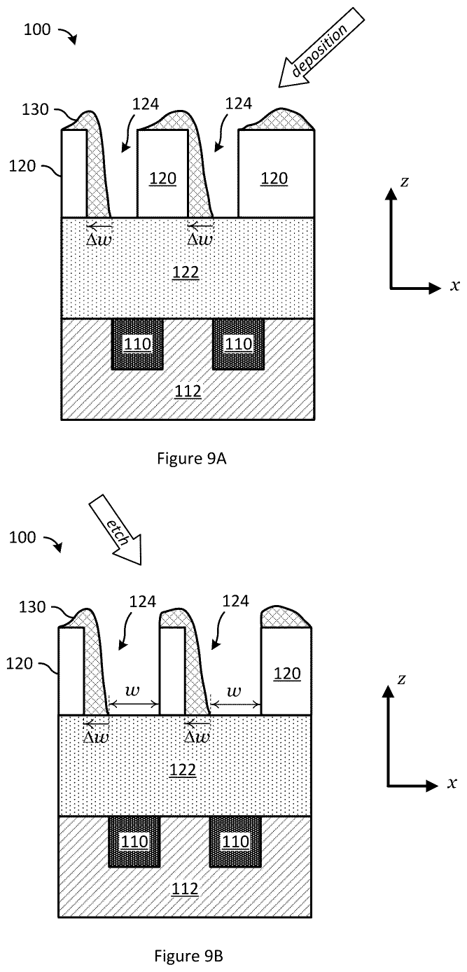

While FIGS. 1A-1F and 2A-2F illustrate a sequence of location specific directional etching followed by location specific deposition for overlay correction, the disclosed methods are not limited to this particular process sequence. In various embodiments, location specific deposition may be performed as the first step followed by location specific directional etching, as illustrated in FIGS. 9A-12B. FIGS. 9A-12B demonstrate various embodiments of this deposition-first methodology, showing how location specific deposition and location specific directional etching can be combined in different sequences to achieve effective overlay correction while maintaining precise control over feature dimensions and alignment. The deposition-first approach may offer advantages such as better process control when working with sensitive materials, reduced risk of over-etching, or improved compatibility with certain equipment configurations. The etch-first approach described previously may provide advantages in terms of more predictable material removal and better control over final dimensions.

FIGS. 9A-9B illustrate cross-sectional views of an overlay correction method with location specific deposition followed by location specific directional etching, in accordance with an embodiment.

FIG. 9A illustrates the result after performing location specific deposition on the substrate 100 with overlay misalignment. The location specific deposition process may deposit the material 130 along the sidewalls (or a first sidewall of the opening 124) and top surfaces of the second patterned layer 120, reducing the width of opening 124 by Δw along the negative x-direction. The location specific deposition process may also deposit the material 130 on a bottom surface of the opening 124. The location specific deposition process may not deposit the material 130 substantially along a second sidewall different from the first sidewall, where the second sidewall may be opposite to the first sidewall. The location specific deposition methods employed may be similar to those described previously with reference to FIGS. 1D and 2D, including GCB deposition or other directional deposition techniques that enable precise material placement on specific surfaces. In some embodiments, the selective deposition process in FIG. 9A may be performed using angled deposition techniques where the deposition beam approaches the substrate at controlled non-perpendicular angles. This angled location specific deposition enables preferential material placement along the first sidewall of the opening 124 while substantially avoiding deposition along the second sidewall through geometric effects and controlled beam positioning.

FIG. 9B shows the result after applying a location specific directional etching process to complete the overlay correction. The location specific directional etching process may be similar to that described in FIGS. 1B and 2B, utilizing a tilted particle flux (which may form an angle relative to the second patterned layer 120) to selectively remove material and push the opening boundary along the positive x-direction (or removing materials from the second sidewall) to extend the opening 124 by Δw. The location specific directional etching process may also remove at least a portion of the deposited material 130 that was previously deposited during the location specific deposition step, particularly material disposed on surfaces that are exposed to the directional flux. This location specific directional etching step fine-tunes the opening position and dimension to achieve the target width w and proper alignment with the features of the first patterned layer 110. The combination of initial location specific deposition followed by location specific directional etching collectively adjusts both the position and dimensions of the opening 124 to reduce overlay misalignment while maintaining the desired feature geometry. This deposition-first approach may offer advantages such as improved process control, reduced complexity in certain material systems, or better compatibility with specific equipment configurations.

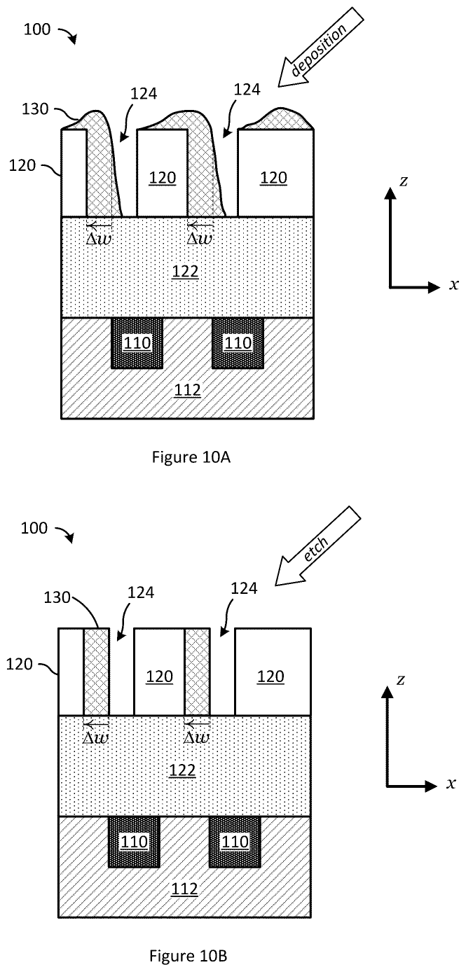

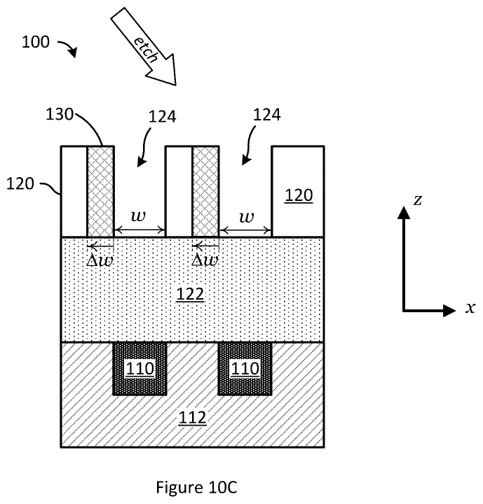

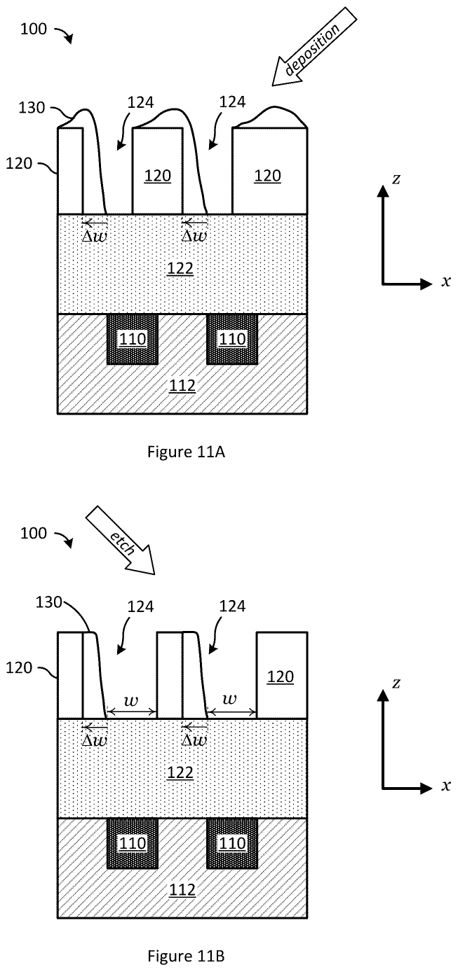

FIGS. 10A-10C illustrate cross-sectional views of an overdeposition and corrective etching sequence for overlay correction, in accordance with an embodiment.

FIG. 10A illustrates the result after performing location specific deposition with an overcompensation, similar to the approach described in FIG. 8B. The deposited material 130 may be selectively deposited (along sidewall of the second patterned layer 120 or on the bottom surface of the opening 124) to reduce the width of opening 124 by more than the target correction amount Δw.

FIG. 10B shows the result after applying a corrective etching process to adjust the deposited material thickness to the target correction amount Δw. The corrective etching may be similar to the etching described in FIG. 8C, utilizing either directional or non-directional etching techniques. This corrective etching step removes excess deposited material 130 within the opening 124 while preserving the desired amount of material to achieve the target dimensional correction, resulting in a material spacer with thickness corresponding to Δw. The corrective etching may also remove the deposited material 130 over the second patterned layer 120.

FIG. 10C illustrates the final step where location specific directional etching, similar to that described in FIGS. 2B and 9B, is applied to push the opening 124 boundary along the positive x-direction by Δw. This location specific directional etching process extends the opening 124 dimension and fine-tunes the alignment with the underlying features of the first patterned layer 110.

FIGS. 11A-11B illustrate cross-sectional views of another location specific deposition variation for overlay correction, in accordance with an embodiment. This embodiment demonstrates a material-matching approach where the deposited material comprises the similar material composition as the underlying patterned layer, providing advantages in etch selectivity and process integration.

FIG. 11A illustrates the result after performing location specific deposition where the deposited material 130 may comprise the similar material as the second patterned layer 120. This similar-material approach may provide benefits such as improved etch rate matching, reduced material compatibility issues, and simplified process integration for subsequent etching steps. The location specific deposition process may deposit the deposited material 130 to reduce the opening 124 dimension by Δw, partially correcting the overlay misalignment. The same-material deposition may be achieved through various techniques, similar to those described in FIGS. 1D and 2D, that can deposit materials matching the composition of the second patterned layer 120. For example, if the second patterned layer 120 comprises carbon-based materials, the deposited material 130 may also comprise carbon-based materials with similar chemical and physical properties.

The term “similar material” as used herein refers to materials that exhibit comparable chemical composition, physical properties, or processing characteristics to enable compatible etch rates and process integration. Similar materials may include materials with substantially the same base composition but with minor variations in dopant levels, impurity content, or processing conditions that do not significantly affect the functional properties for overlay correction applications. In various embodiments, similar materials may exhibit etch rate ratios within a factor of approximately 2:1 or less when subjected to the same etch chemistry, enabling effective simultaneous processing of both the deposited material and the underlying patterned layer.

FIG. 11B shows the result after applying a location specific directional etching that can etch both the deposited material 130 and the second patterned layer 120 simultaneously due to their matching material composition. The location specific directional etching process may remove the deposited material 130 from the top surface of the second patterned layer 120, creating a clean interface and eliminating excess material that could interfere with subsequent processing steps. Simultaneously, the location specific directional etching may push the opening 124 boundary along the positive x-direction to extend the opening 124 and achieve the target width w with proper alignment to the underlying features of the first patterned layer 110. This same-material approach enables the location specific directional etching process to achieve both material cleanup and dimensional correction in a single step, as the etch chemistry and process parameters can be optimized for the common material composition.

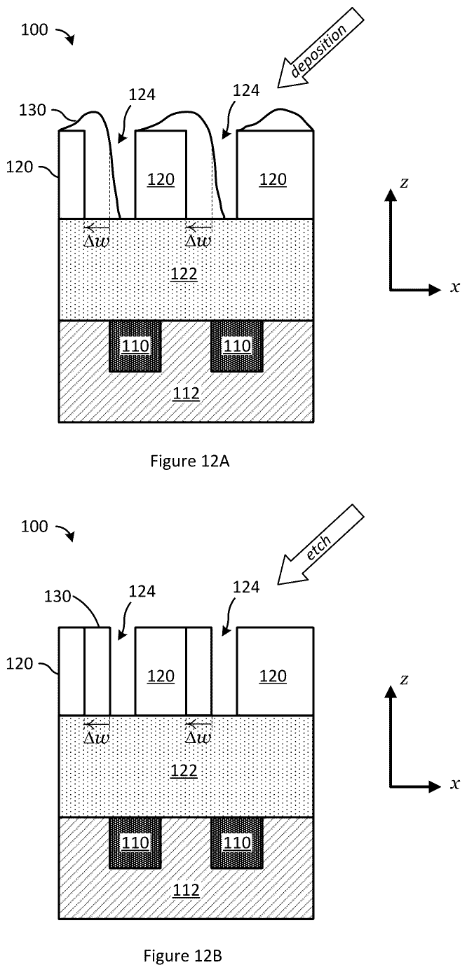

FIGS. 12A-12B illustrate cross-sectional views of an alternative same-material processing sequence for overlay correction, in accordance with an embodiment. This embodiment demonstrates a variation of the same-material approach described in FIGS. 11A-11B, with overdeposition followed by corrective etching to achieve enhanced process control.

FIG. 12A illustrates the result after performing location specific deposition with an overcompensation, where the deposited material 130 comprises the similar material as the second patterned layer 120. Similar to the overdeposition approach described in FIG. 10A, the location specific deposition process deposits material 130 to reduce the opening 124 dimension by more than the target correction amount Δw. FIG. 12B shows the result after applying corrective etching to adjust the deposited material thickness to the target correction amount Δw, similar to the process described in FIGS. 8C and 10B. Following the corrective etching shown in FIG. 12B, a location specific directional etching process similar to that described in FIG. 11B may be applied to extend the opening 124 to achieve the final target width w with proper alignment to the underlying features of the first patterned layer 110.

After completing the location specific directional etching process to align the opening with the features of the first patterned layer 110, as described in FIGS. 9B, 10C, 11B, and the subsequent location specific directional etching following FIG. 12B, the processing may proceed with additional steps similar to those described in FIGS. 1E-1F and 2E-2F.

The combination of location specific directional etching and deposition processes disclosed herein addresses issues that arise from etched-only overlay correction approaches, which may create potential problems when the extended openings are subsequently filled with conductive materials. The increased width (w+Δw) of etched-only corrected openings reduces the spacing between adjacent openings, which can lead to undesirable proximity between conductors after conductive fill. This reduced spacing potentially causes electrical shorts, increased capacitance effects, or crosstalk between adjacent features, compromising device performance and reliability. By combining location specific directional etching with location specific deposition, the disclosed methods may first extend the openings to achieve proper alignment with underlying features, and then apply a second location specific directional process to selectively deposit material and reduce the opening dimension by the distance Δw. This approach restores the original opening width w while preserving the improved overlay alignment, thereby maintaining proper spacing between adjacent features and avoiding the electrical performance issues associated with etching-only correction methods. The sequential application of location specific directional etching and location specific deposition (or sequential application of location specific deposition and location specific directional etching) enables precise control over both the position and dimensions of the corrected openings, providing improved overlay correction without compromising feature spacing or electrical characteristics.

FIGS. 3A-3D illustrate top views of a variation of the overlay misalignment correction method showing rectangular openings or trenches instead of circular via openings, in accordance with an embodiment.

FIG. 3A illustrates a top view of the substrate 100 in FIG. 2B showing a variation of the second patterned layer 120 comprising rectangular openings 124 with width w and length l, which may be misaligned with respect to the underlying features of the first patterned layer 110 in both the x-axis and y-axis directions. The misalignment may be characterized by offset distances Δw in the x-direction and Δl in the y-direction.

FIG. 3B illustrates a top view corresponding to the processing stage of FIGS. 1C and 2C, showing the result after applying location specific directional processes to correct the misalignment. A first location specific directional process such as location specific directional etching may be applied along a first direction, such as the positive x-axis, to extend the dimension of the openings 124 along the x-axis by Δw. Subsequently, the substrate 100 may be rotated azimuthally, and location specific directional etching may be applied along a different direction, such as the negative y-direction, to extend the opening dimension by Δl in the y-direction. The location specific directional etching may be similar to the location specific directional etching described with reference to 1B-1C and 2B-2C.

FIG. 3C illustrates a top view corresponding to the processing stage of FIGS. 1D and 2D, showing the result after applying a second location specific directional process. Directional or location specific deposition may be applied along second directions, such as the negative x-direction and positive y-direction, to reduce the opening dimensions by Δw and Δl respectively through backfilling the sidewalls of the openings with deposited material 130. This location specific deposition process restores the opening dimensions to the original width w and length l while maintaining the corrected alignment with the underlying features of the first patterned layer 110. The deposited material 130 may be strategically deposited to compensate for the previous extensions, resulting in properly sized and aligned rectangular openings. In various embodiments, the directional or location specific deposition method used may be similar to the methods described previously with reference to FIGS. 1D and 2D. Afterwards, an etching process may be applied to the second separation layer 122 using the second patterned layer 120 as an etch mask, similar to the process described in FIGS. 1E and 2E. This may expose the top surfaces of the first patterned layer 110 through the openings 124, similar to FIG. 1E.

FIG. 3D illustrates a top view corresponding to the final processing stages of FIGS. 1F and 2F, showing the completed structure after conductive material filling and planarization. A conductive filling process may deposit conductive material 132 to fill the corrected rectangular openings, similar to the process described in FIGS. 1F and 2F. Subsequently, a planarization process such as CMP may be applied to remove excess conductive material and create a smooth upper surface. The final structure demonstrates successful correction of the two-dimensional overlay misalignment, resulting in properly aligned rectangular conductive features that provide reliable electrical connections to the underlying first patterned layer 110 while maintaining the desired feature dimensions and spacing.

Similar to the embodiments described in FIGS. 9A-12B, the location specific directional etching and deposition sequence shown in FIGS. 3A-3D can be switched to achieve the same overlay correction results. For example, starting from the misaligned state in FIG. 3A, a directional deposition process may be first applied to reduce the opening dimensions by depositing material along specific sidewalls, followed by location specific directional etching processes to extend the openings in the required directions to achieve proper alignment with the underlying features. This alternative sequence provides flexibility in process integration and may offer advantages depending on the specific materials, equipment capabilities, or manufacturing constraints. Furthermore, while the embodiment in FIGS. 3A-3D demonstrates correction of two-dimensional misalignment in orthogonal x and y directions, the disclosed methods are not limited to two-dimensional corrections. In various embodiments, overlay misalignment may occur in more than two directions, requiring correction along multiple non-orthogonal axes or involving rotational misalignment components. In such embodiments, location specific directional etching or deposition processes can be applied sequentially along different directions by rotating the substrate azimuthally between each location specific directional process. The substrate rotation allows the directional flux to be oriented along any desired direction relative to the substrate features, enabling comprehensive correction of complex multi-dimensional overlay errors through a series of targeted directional material modification steps.

FIGS. 4A-4B illustrate cross-sectional views and FIGS. 5A-5B illustrate corresponding top views of an alternative embodiment using conformal deposition followed by location specific directional etching to reduce overlay misalignment, in accordance with an embodiment. This approach provides a different method for correcting overlay misalignment by first applying a blanket conformal coating and then selectively removing portions of the coating through location specific directional etching processes.

FIG. 4A illustrates a cross-sectional view and FIG. 5A illustrates a corresponding top view of the substrate 100 after the etching process described in FIGS. 1C and 2C, followed by conformal deposition of a material layer 330. The material layer 330 may comprise similar materials to the deposited material 130 described in previous embodiments, such as carbon-containing materials, silicon-containing materials, or other suitable materials. The conformal deposition process may deposit the material layer 330 uniformly over the exposed surfaces of the substrate 100, including surfaces of the second separation layer 122 and the second patterned layer 120. In various embodiments, this conformal coating technique may be achieved through processes such as atomic layer deposition (ALD), chemical vapor deposition (CVD), or other conformal deposition methods that provide uniform thickness coverage over complex topographies.

FIG. 4B illustrates a cross-sectional view and FIG. 5B illustrates a corresponding top view showing the result after applying a location specific directional etching process to selectively remove portions of the material layer 330. The location specific directional etching process may be applied along a first direction, such as the positive x-direction, and may be similar to the location specific directional etching process described with reference to FIGS. 1B and 2B. The location specific directional etching process may selectively remove a portion of the material layer 330 within the openings 124, particularly the portion above the first patterned layer 110. The directional nature of the etching process allows for selective material removal that modifies the effective dimension of the openings 124 to width w, achieving proper alignment with the underlying first patterned layer 110. This approach combines the advantages of uniform conformal deposition with the precision of location specific directional etching to reduce overlay misalignment while maintaining control over the final opening dimensions and alignment. After the processing steps shown in FIGS. 4B and 5B, the substrate may subsequently undergo the etching process and conductive material filling described in FIGS. 1E-1F and 2E-2F.

FIGS. 6A-6F and FIGS. 7A-7F illustrate cross-sectional and top views of an embodiment demonstrating location specific processing with customized correction parameters, respectively, in accordance with an embodiment.

FIGS. 6A and 7A illustrate a location specific processing embodiment for correcting overlay misalignments that vary across different regions of a substrate, in accordance with an embodiment. FIG. 6A shows a top view of substrate 500 demonstrating location specific overlay misalignment at different locations across the wafer, while FIG. 7A shows a cross-sectional view of the substrate 500 along line 7A-7A′ indicated in FIG. 6A. FIG. 6A illustrates a simpler case showing across-wafer overlay errors where the error progresses from being negative to positive from end of the wafer to the other.

The substrate 500 may comprise a first patterned layer 510, a first separation layer 512, a second separation layer 522, and a second patterned layer 520 with openings 524a-e. The second patterned layer 520 may comprise similar materials and be formed using similar deposition methods to the second patterned layer 120 described previously. Similarly, the second separation layer 522 may comprise similar materials to the second separation layer 122, the first patterned layer 510 may comprise similar materials to the first patterned layer 110, and the first separation layer 512 may comprise similar materials to the first separation layer 112.

As illustrated in FIG. 6A, different locations across the substrate 500 exhibit varying degrees of overlay misalignment between the openings 524a-e of the second patterned layer 520 and line features of the first patterned layer 510. In various embodiments, a first location may show an overlay misalignment of Δw₁ in the negative x-direction, a second location may show a misalignment of Δw₂ in the positive x-direction, a third location may show a misalignment of Δw₃ in the negative y-direction, and a fourth location may show a misalignment of Δw₄ in the positive y-direction. These varying misalignments across the substrate demonstrate the non-uniform nature of overlay errors that can result from factors such as substrate distortion, thermal effects, equipment variations, or process-induced shifts.

The overlay misalignment map may be obtained by measuring overlay misalignments across the substrate using overlay metrology techniques comprising optical overlay measurement or electron beam overlay measurement as described previously. These measurements may be performed at multiple locations across the substrate to generate a comprehensive overlay misalignment map that characterizes the magnitude and direction of misalignment at each location.

Based on the overlay misalignment map, location specific correction parameters may be generated to reduce the overlay misalignments at each location. The location specific correction parameters may comprise directional angles, deposition thicknesses, etch depths, beam positions, process durations, or material selection parameters customized for each location based on the specific misalignment characteristics identified in the overlay misalignment map. For example, the first location with misalignment of a first dimension Δw₁ may require location specific directional etching along the positive x-direction with specific beam angle and etch depth parameters, while the second location with misalignment of a second dimension Δw₂ may require location specific deposition along the negative x-direction with specific thickness and material parameters. The first dimension and the second dimension may be different. The generation of location specific correction parameters may comprise using an artificial intelligence or machine learning algorithm, such as location specific process (LSP) algorithm, to analyze the overlay misalignment map and formulate optimized correction strategies for different locations of the substrate.

FIGS. 6B and 7B illustrate the application of location specific directional processes to correct the varying overlay misalignments identified in FIGS. 6A and 7A, in accordance with an embodiment. In various embodiments, the location specific directional processes may address collective overlay errors within defined areas rather than correcting individual features independently, achieving optimal overall results within each processing region by considering the collective misalignment characteristics of multiple features simultaneously.

FIG. 6B shows a top view and FIG. 7B shows a corresponding cross-sectional view along line 7B-7B′ after performing a first location specific directional etching process. Being a location specific process, the error correction can be dialed in for each location across the substrate. The location specific directional etching process may comprise a scanning beam that traverses the substrate 500 with dynamically adjusted correction parameters based on the overlay misalignment map generated from the metrology measurements.

The location specific directional etching process may involve scanning the directional beam (or referred to as incident flux) first along the x-direction (or y-direction) across the substrate 500, then along the y-direction (or x-direction), with correction parameters such as scanning speed, beam angle, particle flux intensity, etch depth, and process duration continuously adjusted based on the local overlay misalignment characteristics at each location. The location specific directional etching process may be similar to that described in FIGS. 1B and 2B, utilizing a tilted particle flux to selectively remove material from specific sidewalls of the openings, but with the added capability of continuous parameter adjustment during the scanning process.

During the scanning process, the beam may transition from positive x-direction corrections to negative x-direction corrections as it moves across the substrate 500, addressing the across-wafer overlay error patterns that transition from negative to positive. At locations requiring correction in the positive x-direction, such as the first location of opening 524a, the beam may be tilted and the flux intensity (or scanning speed) increased to extend the opening dimension by Δw₁. At the second location of opening 524c, the beam may be adjusted to extend the opening dimension by Δw₂ in the negative x-direction. At locations such as opening 524b where the overlay alignment is acceptable, minimal or no etching may be applied.

Similarly, when scanning in the y-direction, the beam may address corrections in both positive and negative y-directions as needed. At locations requiring correction in the negative y-direction, such as the third location of opening 524d, the beam parameters may be adjusted to extend the opening dimension by Δw₃ in the negative y-direction, while at the fourth location of opening 524e, the beam may extend the opening dimension by Δw₄ in the positive y-direction.

FIGS. 6C and 7C illustrate the application of a second location specific directional process such as a location specific directional (or selective) deposition process to restore the original opening dimensions while maintaining the corrected alignment achieved in the previous etching steps, in accordance with an embodiment. FIG. 6C shows a top view and FIG. 7C shows a corresponding cross-sectional view along line 7C-7C′ after performing location specific location specific deposition processes.

In various embodiments, the location specific deposition process may involve scanning the directional deposition beam (or referred to as location specific deposition beam) first along the x-direction (or y-direction) across the substrate 500, then along the y-direction (or x-direction), with correction parameters such as beam angle, deposition flux intensity, deposition thickness, and process duration continuously adjusted based on the local overlay correction requirements at each location. The location specific deposition process may be similar to that described in FIGS. 1D and 2D, utilizing directional or angled deposition techniques such as GCB deposition, AS-ALD, or other directional or angled deposition methods to selectively deposit material on specific sidewalls, but with the additional capability of continuous parameter adjustment during the scanning process.

During the scanning process, the deposition beam may transition from depositing along negative x-direction sidewalls to positive x-direction sidewalls as it moves across the substrate 500, addressing the need to restore opening dimensions after the previous location specific directional etching corrections. At the first location of opening 524a, the deposition beam may be directed along the negative x-direction to deposit material 530 and reduce the opening dimension by Δw₁, restoring the width to the original dimension w. At the second location of opening 524c, the deposition beam may be adjusted to deposit material along the positive x-direction sidewall, reducing the opening dimension by Δw₂ and restoring the original width w. At locations such as opening 524b where minimal etching was applied, minimal or no deposition may be performed.

Similarly, when scanning in the y-direction, the deposition beam may address dimension restoration in both positive and negative y-directions as needed. At the third location of opening 524d, the deposition beam parameters may be adjusted to deposit material along the positive y-direction sidewall, reducing the opening dimension by Δw₃, while at the fourth location of opening 524e, the beam may deposit material along the negative y-direction sidewall to reduce the opening dimension by Δw₄. The directional deposition process may create dielectric spacers along the extended sidewalls of the openings, reducing the opening widths from their extended dimensions back to the original width w while maintaining the improved alignment with the underlying first patterned layer 510.

In various embodiments, the first and second location specific directional processes may be achieved through movement of the substrate instead of beam scanning, or through combinations of substrate movement and beam adjustment. In certain embodiments, the substrate 500 may be positioned on a movable stage that can translate in x and y directions, allowing different regions of the substrate 500 to be sequentially positioned under a stationary or semi-stationary directional beam. As the substrate 500 moves to position each location under the beam, the beam parameters such as tilt angle, flux intensity, and exposure duration may be adjusted according to the location specific correction parameters for that particular region. In some embodiments, the substrate movement may be combined with beam scanning to provide enhanced flexibility and coverage, where coarse positioning may be achieved through substrate translation while fine adjustments and local corrections may be accomplished through beam steering or tilting. In some embodiments, the substrate 500 may also be rotated azimuthally to orient different crystallographic directions or feature orientations relative to the beam direction, enabling optimal correction for features aligned in various directions across the substrate 500. This combination of substrate movement and beam control may provide comprehensive spatial control for location specific overlay correction while accommodating various equipment configurations and processing requirements.

In various embodiments, the deposited material 530 may comprise similar materials and properties to the deposited material 130 described in previous embodiments. In various embodiments, the deposited material 530 may be deposited over the sidewalls of the second patterned layer 520, while in some embodiments, the deposition may occur on both sidewalls and top surfaces of the second patterned layer 520, depending on the specific deposition technique and process parameters employed. Similar to the embodiments shown in FIGS. 8A-8C, the deposited material 530 may exhibit various profile geometries, ranging from rectangular cross-sections to more irregular or curved profiles.

Similar to the embodiments described in FIGS. 9A-12B, the sequence shown in FIGS. 6B and 6C can be switched to achieve the same overlay correction results through alternative process ordering. For example, at the first location, a location specific deposition process may be first applied to reduce the opening dimension by Δw₁, followed by a location specific directional etching process to extend the opening by Δw₁ in the appropriate direction to achieve proper alignment. This alternative sequence of deposition-first followed by etching provides flexibility in process integration and may offer advantages depending on the specific materials, equipment capabilities, or manufacturing constraints. The location specific correction parameters can be adapted to accommodate either process sequence, with the artificial intelligence or machine learning algorithm determining the optimal combination of deposition and etching steps for each location based on the overlay misalignment characteristics and available processing options.

In various embodiments, different location specific directional processes (e.g., the location specific directional etching process or the location specific deposition process) may be performed simultaneously at different locations of the substrate using multiple processing tools or multiple beams. In some embodiments, the location specific directional etching process may be applied at the first location along the first direction, and the location specific deposition process may be simultaneously applied at the first location along the second direction. This parallel processing approach may be achieved through multiple ion beam sources, multiple gas cluster beam nozzles, or other multi-beam processing systems that can independently control beam parameters such as directional angles, flux intensity, and beam positioning for different regions of the substrate. Similarly, location specific deposition processes may be performed simultaneously at multiple locations using techniques such as multiple rastering nozzles for location specific atomic layer deposition or parallel gas cluster beam deposition systems. This simultaneous processing capability improves throughput and manufacturing efficiency while maintaining the precision and customization benefits of location specific overlay correction.

In various embodiments, the location specific directional processes described in FIGS. 6B-6C and 7B-7C may be implemented based on the correction parameters determined for each specific location on the substrate. At the first location, the first location specific directional process may be performed selectively at that location to reduce the overlay misalignment at the first location, while at the second location different from the first location, a second location specific directional process is performed selectively at the second location to reduce the overlay misalignment at that second location. As described previously, the location specific correction parameters may comprise directional angles for controlling the flux orientation, deposition thicknesses for determining the amount of material to be deposited, etch depths for controlling the extent of material removal, beam positions for targeting specific areas within openings, process durations for controlling the exposure time at each location, and material selection parameters for choosing optimal materials based on the local layer stack composition and correction requirements. These parameters may be customized for each location based on the overlay misalignment map, enabling precise and targeted correction that addresses the specific misalignment characteristics at each location across the substrate. The ability to independently control these multiple process parameters at different locations provides the flexibility needed to correct complex, non-uniform overlay error patterns while maintaining optimal feature geometry and electrical performance.

FIGS. 6D and 7D illustrate an etching process to transfer patterns in the second patterned layer 520 into the second separation layer 522 using the corrected second patterned layer 520 as an etch mask, similar to the process described in FIGS. 1E and 2E. This pattern transfer step preserves the location specific overlay corrections achieved in the previous directional processes while extending the corrected openings through the underlying separation layer to approach the features of the first patterned layer 510. In some embodiments, the deposited material 530 over top surface of the second patterned layer 520 may be removed first before the etching process.

FIGS. 6E and 7E illustrate the substrate 500 after conductive material filling and planarization processes similar to those described in FIGS. 1F and 2F, in accordance with an embodiment. FIG. 6E shows a top view and FIG. 7E shows a corresponding cross-sectional view along line 7E-7E′ after removing the second patterned layer 520 and filling the corrected openings with conductive materials.

In this processing step, the second patterned layer 520 may be removed to expose the corrected openings that extend through the second separation layer 522 down to the underlying first patterned layer 510. Subsequently, conductive material 532 may be deposited to fill the corrected openings and establish electrical connections to the first patterned layer 510. The conductive material 532 may comprise similar materials and be deposited using similar techniques to the conductive material 132 described in previous embodiments, such as copper, tungsten, aluminum, or other suitable conductive materials deposited through PVD, CVD, ALD, or electrochemical plating methods.

As shown in FIG. 7E, the conductive material 532 may fill the corrected openings that have been precisely aligned with the underlying first patterned layer 510 through the location specific directional processes. Following the conductive material deposition, a planarization process such as CMP may be applied to remove excess conductive material from the upper surface and create a smooth, planar topography, similar to the process described in FIGS. 1F and 2F. The final structure demonstrates the successful implementation of location specific overlay correction, resulting in well-aligned conductive interconnects across different regions of the substrate with improved electrical performance and uniform feature spacing.

FIGS. 6F and 7F illustrate further processing steps showing the formation of additional layers with proper alignment to underlying features, demonstrating the scalability and repeatability of the disclosed overlay correction techniques, in accordance with an embodiment. FIG. 6F shows a top view and FIG. 7F shows a corresponding cross-sectional view along line 7F-7F′ after forming additional device layers above the corrected interconnect structure.

In this embodiment, additional layers may be formed over the completed interconnect structure to continue the multilayer device fabrication process. A third separation layer 540 may be formed over the planarized surface of the substrate 500, which may comprise similar materials and be deposited using similar techniques to the second separation layer 522 described previously, such as low dielectric constant silicon oxide or other suitable interlayer dielectric materials. Subsequently, additional conductive features 542 may be formed in the third separation layer 540, which may comprise similar materials and be formed using similar processes to the conductive material 532, such as copper, tungsten, or other suitable conductive materials for interconnect applications.

The formation of these additional layers demonstrates that the overlay correction techniques disclosed herein can be applied repeatedly at multiple levels of a multilayer structure to maintain proper alignment throughout the device fabrication process. The corrected alignment achieved in the lower levels provides a solid foundation for subsequent layer formation, ensuring that overlay errors do not accumulate or propagate through the multilayer stack. This iterative approach enables the fabrication of complex multilayer devices with improved electrical performance, higher yield, and better reliability compared to conventional overlay correction methods. The process can be repeated for additional layers as needed, with each level benefiting from the precise alignment control provided by the location specific directional material modification techniques, resulting in a complete multilayer interconnect structure with uniform electrical characteristics and optimal device performance across the entire substrate.

FIG. 13 illustrates a flow diagram of a method for overlay misalignment correction using location specific directional processes, in accordance with an embodiment. At block 1302, an overlay misalignment may be measured between an opening of a second patterned layer disposed over a first patterned layer and a feature of the first patterned layer. The measurement may be performed using overlay metrology techniques as described with reference to FIGS. 1A-1B, where the substrate 100 may comprise the first patterned layer 110 with a feature (e.g., parallel lines) and the second patterned layer 120 with openings 124.

At block 1304, based on the measured overlay misalignment, a first location specific directional process may be performed to adjust a first dimension of the opening in a first direction. In some embodiments, this first directional process may comprise location specific directional etching as described with reference to FIGS. 1B-1C, using techniques such as GCB etching, ion beam etching, or reactive ion etching with controlled beam angles and substrate tilting. The location specific directional etching may extend the opening dimension by Δw in the required direction to compensate for the overlay misalignment, following the methods and conditions described in reference to FIGS. 1B-1C and similar processes shown in FIGS. 3A-3B for trench structures. In alternative embodiments, this first directional process may comprise location specific deposition as described with reference to FIG. 1D, using techniques such as GCB deposition, AS-ALD, or other directional deposition methods. The deposition-first approach is further illustrated in FIGS. 9A-12B, where location specific deposition is performed as the initial correction step.

At block 1306, based on the measured overlay misalignment, a second location specific directional process may be performed to adjust a second dimension of the opening in a second direction different from the first direction. In some embodiments, as described with reference to FIGS. 1B-1D, 3A-3D, and 8A-8C, this second directional process may comprise a location specific deposition process to restore the original width w while maintaining the corrected alignment. Alternatively, the second location specific directional process may be the location specific directional etching following the location specific deposition as illustrated in FIGS. 9A-12B. The first and the second directional material modification processes may collectively reduce the overlay misalignment.

While not explicitly shown in the flowchart, additional steps may be performed as described in the previous figures. For example, pattern transfer etching may be performed on the second separation layer 122 using the corrected second patterned layer 120 as an etch mask, as illustrated in FIG. 1E. Additionally, conductive material filling and planarization processes may be performed as described in FIG. 1F to complete the interconnect formation. Alternative embodiments may include location specific directional processing with customized correction parameters as described with reference to FIGS. 6A-7F. These additional steps may be implemented as needed based on specific overlay correction requirements and device integration needs.

FIG. 14 illustrates a flow diagram of a method for location specific overlay misalignment correction across a substrate, in accordance with an embodiment.

At block 1402, a substrate may be provided comprising a second patterned layer disposed over a first patterned layer. The substrate may be the substrate 500 as described with reference to FIG. 6A, which may comprise the first patterned layer 510, first separation layer 512, second separation layer 522, and second patterned layer 520 with openings 524. In various embodiments, the second patterned layer 520 may comprise materials such as photoresist, MOR, CAR, or hard mask materials, while the second separation layer 522 may comprise a stack of organic materials, inorganic materials, dielectric materials, or hard mask materials as described previously.

At block 1404, overlay misalignments may be measured across the substrate to generate an overlay misalignment map between the second patterned layer and the first patterned layer. As described with reference to FIG. 6A, the overlay measurements may identify varying misalignments such as Δw₁, Δw₂, Δw₃, and Δw₄ at different locations across the substrate 500 between a pattern of openings in the second patterned layer and a pattern of features (e.g., parallel lines) in the first patterned layer.

At block 1406, location specific correction parameters may be generated based on the overlay misalignment map. In various embodiments, the correction parameters may comprise directional angles, deposition thicknesses, etch depths, beam positions, process durations, or material selection parameters customized for each location based on the specific misalignment characteristics. The correction parameters generation may utilize artificial intelligence or machine learning algorithms to analyze the overlay misalignment map and formulate optimized correction strategies for different regions of the substrate.

At block 1408, based on the correction parameters at a first location, a first location specific directional process may be performed selectively at the first location to reduce the overlay misalignment at that location. In various embodiments, the first location specific directional process may be a location specific directional etching process to extend a dimension of openings at the first location or a location specific deposition process to reduce a dimension of openings at the first location. In various embodiments, additional location specific directional processes may be applied at the first location to further modify the dimension of the opening to collectively reduce overlay misalignment.

At block 1410, based on the correction parameters at a second location different from the first location, a second location specific directional process may be performed selectively at the second location to reduce the overlay misalignment at the second location. In various embodiments, the second location specific directional process may be a location specific directional etching process to extend a dimension of openings at the second location or a location specific deposition process to reduce a dimension of openings at the second location. In various embodiments, additional location specific directional processes may be applied at the second location to further modify the dimension of the opening to collectively reduce overlay misalignment.

While not explicitly shown in the flowchart, additional steps may be performed as described in the previous figures. For example, location specific deposition processes may be applied to restore original opening dimensions while maintaining corrected alignment, as illustrated in FIGS. 6C and 7C. Pattern transfer etching and conductive material filling may be performed as described in FIGS. 6D-6E and 7D-7E. Alternative embodiments may include simultaneous processing at multiple locations using multiple processing tools or beams, or alternative process sequences where deposition precedes etching. These additional steps may be implemented based on specific substrate requirements and the complexity of the overlay error patterns across different regions.

While the inventive aspects are described primarily in the context of via formation and overlay correction in semiconductor manufacturing, it should also be appreciated that these inventive aspects may also apply to other multilayer structure fabrication processes including printed circuit board manufacturing, micro-electromechanical systems (MEMS) fabrication, and three-dimensional integrated circuit assembly. In particular, aspects of this disclosure may similarly apply to any application where precise alignment between features in different layers affects electrical performance and where selective material deposition can improve structural integrity and electrical characteristics.

Example embodiments of the invention are described below. Other embodiments can also be understood from the entirety of the specification as well as the claims filed herein.

Example 1. A method for processing a substrate, the method including: measuring an overlay misalignment between a feature of a first patterned layer and an opening of a second patterned layer that is disposed over a first patterned layer; and based on the measured overlay misalignment, performing a location specific directional etching process to extend a first dimension of the opening in a first direction and performing a location specific deposition process to reduce a second dimension of the opening in a second direction different from the first direction, where the location specific directional etching process and location specific deposition process collectively reduce the overlay misalignment.

Example 2. The method of example 1, where the measuring is based on an overlay metrology including optical overlay measurement or electron beam overlay measurement.

Example 3. The method of one of examples 1 or 2, further including a separation layer disposed between the first patterned layer and the second patterned layer, where the separation layer includes one or more material layers including organic materials, inorganic materials, dielectric materials, or hard mask materials.

Example 4. The method of one of examples 1 to 3, further including etching the separation layer using the second patterned layer as an etch mask after performing the location specific deposition process.

Example 5. The method of one of examples 1 to 4, further including performing a conductive material deposition process to fill an opening of the separation layer after the etching to form an electrical connection to the feature of the first patterned layer.

Example 6. The method of one of examples 1 to 5, where the location specific deposition process includes depositing a material in a portion of the opening, the material including a similar material with the second patterned layer.

Example 7. The method of one of examples 1 to 6, where the location specific deposition process includes gas cluster beam (GCB) deposition, inclined physical vapor deposition (PVD), location specific atomic layer deposition (LS-ALD), or area selective atomic layer deposition (AS-ALD), remote plasma with directional focus, ion beam deposition, or ribbon beam deposition.

Example 8. The method of one of examples 1 to 7, where the location specific directional etching process includes reactive ion etching, ion beam etching, gas cluster beam etching, plasma etching with directional focus, or directional chemical etching using precursors including fluorine-containing compounds, chlorine-containing compounds, oxygen-containing compounds, carbon-containing compounds, or hydrogen-containing compounds.

Example 9. The method of one of examples 1 to 8, where the location specific deposition process includes an angled location specific deposition process where an incident beam approaches at angles greater than 0 degrees and less than 90 degrees from surface normal of the substrate.

Example 10. The method of one of examples 1 to 9, where the second patterned layer includes photoresist, metal oxide resist, organic planarization layer, chemically amplified resist, or hard mask material.

Example 11. A method for processing a substrate, the method including: providing a substrate including a second patterned layer disposed over a first patterned layer; measuring overlay misalignments across the substrate to generate an overlay misalignment map between the second patterned layer and the first patterned layer; generating location specific correction parameters to reduce the overlay misalignments based on the overlay misalignment map; based on the location specific correction parameters at a first location, performing a first location specific directional process selectively at the first location to reduce the overlay misalignment at the first location; and based on the location specific correction parameters at a second location different from the first location, performing the first location specific directional process selectively at the second location to reduce the overlay misalignment at the second location.

Example 12. The method of example 11, where the location specific correction parameters include directional angles, deposition thicknesses, etch depths, beam positions, process durations, or material selection parameters customized for each location based on the overlay misalignment map.

Example 13. The method of one of examples 11 or 12, where generating the location specific correction parameters includes using an artificial intelligence or machine learning algorithm to analyze the overlay misalignment map and formulate correction parameters for different locations of the substrate.

Example 14. The method of one of examples 11 to 13, where the first location specific directional process includes: a location specific directional etching process to expand an opening of the second patterned layer by removing material from the second patterned layer; or a location specific deposition process to reduce a dimension of an opening of the second patterned layer by depositing material in a portion of the opening.

Example 15. The method of one of examples 11 to 14, where the location specific deposition process includes inclined physical vapor deposition (PVD), gas cluster beam (GCB), location specific atomic layer deposition (LS-ALD), area selective atomic layer deposition (AS-ALD), remote plasma with directional focus, ion beam deposition, or ribbon beam deposition.

Example 16. The method of one of examples 11 to 15, where the location specific directional etching process includes reactive ion etching, ion beam etching, gas cluster beam etching, plasma etching with directional focus, or directional chemical etching using precursors including fluorine-containing compounds, chlorine-containing compounds, oxygen-containing compounds, or hydrogen-containing compounds.

Example 17. The method of one of examples 11 to 16, further including: based on the correction parameters at the first and second locations, performing a second location specific directional process selectively at each location, where the second location specific directional process includes a different material modification technique than the first location specific directional process, and where the first and the second location specific directional processes collectively reduce the overlay misalignment at each location.

Example 18. The method of one of examples 11 to 17, where the second location specific directional process includes: a location specific deposition process to reduce a dimension of an opening of the second patterned layer by depositing material in a portion of the opening; or a location specific directional etching process to extend an opening of the second patterned layer by removing material from the second patterned layer.

Example 19. A method for processing a substrate, the method including: forming an opening in a second patterned layer over a first patterned layer, the opening including a first sidewall and a second sidewall different from the first sidewall; depositing material in the opening along the first sidewall but not along the second sidewall to reduce a first dimension of the opening; and etching the second sidewall at an angle relative to the second patterned layer to increase a second dimension of the opening.

Example 20. The method of example 19, where the material deposited in the opening includes a similar material with the second patterned layer.

Example 21. The method of one of examples 19 or 20, where the depositing further includes depositing the material over a top surface of the second patterned layer.

Example 22. The method of one of examples 19 to 21, where the etching removes at least a portion of the deposited material.

Example 23. The method of one of examples 19 to 22, where the depositing further includes depositing the material on a bottom surface of the opening.

Example 24. The method of one of examples 19 to 23, where the depositing includes a conformal deposition process.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-14 may be combined in further embodiments. It is therefore intended that the appended claims encompass any such modifications or embodiments.

What is claimed is:

1. A method for processing a substrate, the method comprising:
measuring an overlay misalignment between a feature of a first patterned layer and an opening of a second patterned layer that is disposed over a first patterned layer; and
based on the measured overlay misalignment, performing a location specific directional etching process to extend a first dimension of the opening in a first direction and performing a location specific deposition process to reduce a second dimension of the opening in a second direction different from the first direction, wherein the location specific directional etching process and location specific deposition process collectively reduce the overlay misalignment.

2. The method of claim 1, wherein the measuring is based on an overlay metrology comprising optical overlay measurement or electron beam overlay measurement.

3. The method of claim 1, further comprising a separation layer disposed between the first patterned layer and the second patterned layer, wherein the separation layer comprises one or more material layers comprising organic materials, inorganic materials, dielectric materials, or hard mask materials.

4. The method of claim 3, further comprising etching the separation layer using the second patterned layer as an etch mask after performing the location specific deposition process.

5. The method of claim 4, further comprising performing a conductive material deposition process to fill an opening of the separation layer after the etching to form an electrical connection to the feature of the first patterned layer.

6. The method of claim 1, wherein the location specific deposition process comprises depositing a material in a portion of the opening, the material comprising a similar material with the second patterned layer.

7. The method of claim 1, wherein the location specific deposition process comprises gas cluster beam (GCB) deposition, inclined physical vapor deposition (PVD), location specific atomic layer deposition (LS-ALD), or area selective atomic layer deposition (AS-ALD), remote plasma with directional focus, ion beam deposition, or ribbon beam deposition.

8. The method of claim 1, wherein the location specific directional etching process comprises reactive ion etching, ion beam etching, gas cluster beam etching, plasma etching with directional focus, or directional chemical etching using precursors comprising fluorine-containing compounds, chlorine-containing compounds, oxygen-containing compounds, carbon-containing compounds, or hydrogen-containing compounds.

9. The method of claim 1, wherein the location specific deposition process comprises an angled location specific deposition process where an incident beam approaches at angles greater than 0 degrees and less than 90 degrees from surface normal of the substrate.

10. The method of claim 1, wherein the second patterned layer comprises photoresist, metal oxide resist, organic planarization layer, chemically amplified resist, or hard mask material.

11. A method for processing a substrate, the method comprising:
providing a substrate comprising a second patterned layer disposed over a first patterned layer;
measuring overlay misalignments across the substrate to generate an overlay misalignment map between the second patterned layer and the first patterned layer;
generating location specific correction parameters to reduce the overlay misalignments based on the overlay misalignment map;
based on the location specific correction parameters at a first location, performing a first location specific directional process selectively at the first location to reduce the overlay misalignment at the first location; and
based on the location specific correction parameters at a second location different from the first location, performing the first location specific directional process selectively at the second location to reduce the overlay misalignment at the second location.

12. The method of claim 11, wherein the location specific correction parameters comprise directional angles, deposition thicknesses, etch depths, beam positions, process durations, or material selection parameters customized for each location based on the overlay misalignment map.

13. The method of claim 11, wherein generating the location specific correction parameters comprises using an artificial intelligence or machine learning algorithm to analyze the overlay misalignment map and formulate correction parameters for different locations of the substrate.

14. The method of claim 11, wherein the first location specific directional process comprises:
a location specific directional etching process to expand an opening of the second patterned layer by removing material from the second patterned layer; or
a location specific deposition process to reduce a dimension of an opening of the second patterned layer by depositing material in a portion of the opening.

15. The method of claim 14, wherein the location specific deposition process comprises inclined physical vapor deposition (PVD), gas cluster beam (GCB), location specific atomic layer deposition (LS-ALD), area selective atomic layer deposition (AS-ALD), remote plasma with directional focus, ion beam deposition, or ribbon beam deposition.

16. The method of claim 14, wherein the location specific directional etching process comprises reactive ion etching, ion beam etching, gas cluster beam etching, plasma etching with directional focus, or directional chemical etching using precursors comprising fluorine-containing compounds, chlorine-containing compounds, oxygen-containing compounds, or hydrogen-containing compounds.

17. The method of claim 11, further comprising:
based on the location specific correction parameters at the first and second locations, performing a second location specific directional process selectively at each location, wherein the second location specific directional process comprises a different material modification technique than the first location specific directional process, and wherein the first and the second location specific directional processes collectively reduce the overlay misalignments at each location.

18. The method of claim 17, wherein the second location specific directional process comprises:
a location specific deposition process to reduce a dimension of an opening of the second patterned layer by depositing material in a portion of the opening; or
a location specific directional etching process to extend an opening of the second patterned layer by removing material from the second patterned layer.

19. A method for processing a substrate, the method comprising:
forming an opening in a second patterned layer over a first patterned layer, the opening comprising a first sidewall and a second sidewall different from the first sidewall;
depositing material in the opening along the first sidewall but not along the second sidewall to reduce a first dimension of the opening; and
etching the second sidewall at an angle relative to the second patterned layer to increase a second dimension of the opening.

20. The method of claim 19, wherein the material deposited in the opening comprises a similar material with the second patterned layer.

21. The method of claim 19, wherein the depositing further comprises depositing the material over a top surface of the second patterned layer.

22. The method of claim 19, wherein the etching removes at least a portion of the deposited material.

23. The method of claim 19, wherein the depositing further comprises depositing the material on a bottom surface of the opening.

24. The method of claim 19, wherein the depositing comprises a conformal deposition process.
